(19) United States
(12) Patent Application Publication
(10) Pub. No.: US 2022/0399549 A1
(43) Pub. Date: Dec. 15, 2022

(54) POROUS SILICON MEMBRANE MATERIAL, MANUFACTURE THEREOF AND ELECTRONIC DEVICES INCORPORATING SAME

(71) Applicant: THE SUN COMPANY TEXAS, LLC d.b.a. THE SUN COMPANY, Tucson, AZ (US)

(72) Inventors: Ryan G. Redford, Irvine, CA (US); Daniel Carothers, Lucas, TX (US); Janet M. Roveda, Tucson, AZ (US); Joley D. Michaelson, Tucson, AZ (US)

(73) Assignee: THE SUN COMPANY TEXAS, LLC d.b.a. THE SUN COMPANY, Tucson, AZ (US)

(21) Appl. No.: 17/603,469

(22) PCT Filed: Apr. 13, 2020
(86) PCT No.: PCT/US2020/027940

§ 371 Date: Oct. 13, 2021

Related U.S. Application Data
(60) Provisional application No. 62/833,350, filed on Apr. 12, 2019.
(60) Provisional application No. 62/833,453, filed on Apr. 12, 2019.
(60) Provisional application No. 62/833,474, filed on Apr. 12, 2019.
(60) Provisional application No. 62/881,090, filed on Jul. 31, 2019.
(60) Provisional application No. 62/962,740, filed on Jan. 17, 2020.
(60) Provisional application No. 62/962,748, filed on Jan. 17, 2020.
(60) Provisional application No. 62/962,745, filed on Jan. 17, 2020.

(51) Int. Cl. H01M 8/023; H01M 14/00; H01M 8/18; H01M 16/00; H01L 31/053

(52) U.S. Cl. CPC H01M 8/023; H01M 14/005; H01M 8/188; H01M 16/003; H01L 31/053

(57) ABSTRACT

A redox flow battery includes positive and negative electrodes respectfully located in half-cells separated by a porous silicon wafer separator formed by MEMS Technology. The first half cell and the second half cell each preferably include a plurality of dividers or barriers configured to create flow channels which introduce turbulence insuring the electrolytes are changing or mixing at surfaces of the electrodes and the membrane. Also disclosed is a solar energy generation and storage system which includes a photovoltaic cell and an electrochemical energy storage battery which share a common electrode. Also disclosed is a membrane-less redox flow electrical energy storage battery, having a cathode electrode; an anode electrode formed of a porous silicon substrate in which surfaces of the pores of the porous silicon substrate are coated at least in part with a metal silicide; and, an electrolyte.

The present disclosure relates to novel porous silicon material, the manufacture thereof and the use thereof. The disclosure has particular utility in connection with manufacture of porous silicon material for use as a membrane in redox flow energy storage batteries, and to solar photovoltaic (PV) cells having integrated electrical energy storage batteries, and will be described in connection with such utility, although other utilities are contemplated.

Redox flow electrical energy batteries exhibit high energy conversion efficiency, flexible design, high energy storage capacity, flexible location, deep discharge, high safety, environmental friendliness and low maintenance cost compared with other types of energy storage systems and are being adopted for various uses including renewable energy storage for wind energy, solar energy and tidal energy installations, emergency power supply systems, standby power supply systems, and load leveling for conventional power supply systems.

A membrane/separator, being one of the key elements of a redox flow battery, is employed to prevent cross mixing of the positive and negative electrolytes, and for completing the current circuit by transferring protons. Proton conductivity, chemical stability and ion selectivity of the membrane can directly affect the electrochemical performance and useful lifetime of a redox flow battery. Therefore, the membrane should possess a number of properties, including low active species permeability (high ion selectivity), low membrane area resistance (high ion conductivity), high physicochemical stability and low cost. The membranes most commonly used in redox flow batteries are formed of perfluorosulfonic acid polymers such as DuPont Nafion® owing to their high proton conductivity and chemical stability. However, Nafion® membranes are expensive, and exhibit relatively low ion selectivity when used in redox flow batteries, which limits commercialization of redox flow batteries. Thus, there exists a need for better membranes with high ion selectivity, high physicochemical stability and low cost.

The terms “top” and “bottom” and “left” and “right” are employed in a relative, and not an absolute sense to facilitate description and to describe relative locations of elements. The terms can be used interchangeably.

The present disclosure in one aspect provides a method for forming novel porous silicon wafer material and the use thereof as membranes in batteries such as redox flow batteries, and other electronic devices. More particularly, the present disclosure provides a method for forming novel porous silicon wafers for use as membrane separators for redox flow batteries using MEMS (microelectromechanical systems) technology. In accordance with the present disclosure, a silicon wafer is selectively masked using resist deposition and photolithography techniques and selected portions of the wafer are subjected to electrochemical etching to form pores or channels extending through the silicon wafer. Preferably, the channels or pores are substantially cylindrical in shape, and have a relatively high, (e.g., <50:1) depth to cross section dimension aspect ratios.

In one embodiment, pore size, membrane selectivity and ion conductivity are “tuned” by inorganic doping of the silicon wafer to enhance metal ion rejection and proton conductivity, for when the membrane is used as a separation barrier in a redox flow battery.

The disclosure also provides redox flow batteries in which the novel porous silicon wafers are used as membrane materials.

More particularly, the present disclosure also provides a redox flow battery comprising a separator membrane element formed of a porous silicon wafer.

In one embodiment, pores of the porous silicon wafer are substantially cylindrical through holes. Preferably, the cylindrical through holes have a depth to cross section dimension aspect ratio of ≤50:1.

In another embodiment surfaces of pores of the porous silicon wafer are treated to enhance surface ion conductivity. For example, the surfaces of the pores may be oxidized, or the surfaces may be modified by deposition of a metal.

In yet another embodiment, the porous silicon wafer is doped to enhance metal ion rejection and proton conductivity.

The present disclosure also provides a redox flow battery comprising an electrical assembly comprising positive and negative electrodes respectfully located in half-cells separated by a separator, wherein the separator comprises a porous silicon wafer, and including an electrolyte in the half cells.

In one embodiment of the battery, pores of the porous silicon wafer preferably have a depth to cross section dimension aspect ratio of ≤50:1.

In one particular embodiment of the battery the electrolyte is selected from the group consisting of iron-ligand electrolyte, an iron-chloride electrolyte, and iron-chromium electrolyte, a vanadium-based electrolyte, a zinc-based electrolyte, a sulfuric acid-based electrolyte, a hydrochloric acid electrolyte, a zinc-bromide electrolyte, a zinc-iodide electrolyte, a zinc-cerium electrolyte, a zinc-nickel electrolyte, and a zinc-iron electrolyte such as zinc-ferricyanide.

In a preferred embodiment of the battery surfaces of the pores are treated to enhance surface ion conductivity. For example, the surfaces of the pores are oxidized, or the surfaces are modified by deposition of a metal.

In another embodiment of the battery, the porous silicon wafer is doped to enhance metal ion rejection and proton conductivity.

In still yet another aspect of the disclosure, the redox flow battery system further comprises positive and negative current collectors respectfully located in the half-cells. In a particularly preferred embodiment of the disclosure the paired half-cells are arranged in a stack, and at least one of adjacent half-cells in the stack share a common electrode.

In yet another embodiment of the disclosure the separator member comprises a shaped porous silicon wafer having a porous middle section of a first thickness, and solid silicon end sections of a second thickness greater than the middle section.

In still yet another embodiment of the disclosure the redox flow battery system further comprises an electrolyte in the half-cells. Preferably the electrolyte is selected from the group consisting of an iron-ligand electrolyte, an iron-chloride electrolyte, and iron-chromium electrolyte, a vanadium-based electrolyte, a sulfuric acid-based electrolyte, a hydrochloric acid electrolyte, a zinc-bromide electrolyte, a zinc-iodide electrolyte, a zinc-cerium electrolyte, a zinc-nickel electrolyte, and a zinc-iron electrolyte such as zinc-ferricyanide.

The present disclosure also provides a method of forming a separator for use in a redox flow battery, comprising providing a silicon wafer; and etching through holes extending through at least a portion of the wafers, wherein the through holes preferably have a depth to cross section dimension aspect ratio of ≤50:1.

In one embodiment of the method surfaces of the pores are treated to enhance surface ion conductivity. For example, the surfaces of the pores are oxidized, or the surfaces are modified by deposition of a metal.

In yet another embodiment of the method the silicon wafer is doped to enhance metal ion rejection and proton conductivity.

In yet another aspect the present disclosure integrates energy storage battery elements with photovoltaic cell elements whereby to permit direct charging of the battery, thereby eliminating the need for complex electrical distribution and conditioning circuits employed with conventional photovoltaic cells. More particularly, redox flow cell battery elements are integrated with a photovoltaic cell. In accordance with a preferred embodiment of this aspect of the present disclosure, the redox flow battery incorporates a porous silicon membrane formed using MEMS technology. However, the disclosure is not limited to the use of redox flow batteries incorporating porous silicon membranes, and other redox flow battery systems also advantageously may be used.

More particularly, the present disclosure in one aspect provides a solar energy generation and storage system comprising a photovoltaic cell and an electrochemical energy storage battery, wherein the photovoltaic cell and the electrochemical storage battery share a common electrode.

In one preferred aspect, the electrochemical energy storage battery comprises a redox flow battery. In such embodiment, the redox flow battery preferably incorporates a porous silicon membrane or a membrane of a perfluorosulfonic acid polymer.

In various aspects the photovoltaic cell may comprise a silicon solar cell or a gallium arsenide cell; a monocrystalline silicon solar energy cell; a monocrystalline silicon body of P-type conductivity which has been treated to provide a zone of N-type conductivity or a monocrystalline silicon body of N-type conductivity which has been treated to provide a zone of P-type conductivity; a polycrystalline silicon cell; a thin-film solar cell, preferably formed of a semi-conductor material selected from the group consisting of amorphous thin-film silicon, cadmium telluride and copper indium gallium diselenide; or, a multi-junction solar cell, preferably comprising a top cell formed of, e.g., indium gallium phosphide, a middle cell formed of, e.g., indium gallium arsenide, and a bottom cell formed of, e.g., germanium.

In yet another aspect, the process disclosure provides a process and apparatus for providing a superior uniformly etched silicon wafer for use in a redox flow battery as above described, and in particular in forming an integrated energy storage battery and photovoltaic cell as above described.

More particularly, in accordance with one embodiment of our disclosure, a thin interface metal layer is deposited on one side, i.e., the “back side” of a silicon wafer. The silicon wafer metal layer assembly is loaded into an etching fixture, an electrical charge applied to the metal layer deposited on the back side surface of the wafer, and an etchant flowed across the front, i.e., exposed side surface of the wafer. The charge is applied between metal layer on the back side surface of the wafer and the etchant. Also provided are etching fixtures and a system for etching silicon wafers.

The present disclosure also provides improvement over redox flow electrical energy battery constructions of the prior art by providing a plurality of dividers or barriers that divide and/or direct the electrolyte flow in the half cells to add turbulence to the flowing electrolyte and increase mixing of the electrolyte adjacent the electrode surfaces.

In one aspect the disclosure provides redox flow electrical energy storage battery comprising a first half cell and a second half cell separated by a porous membrane; an anode and an analyte electrolyte flowing through the first half cell; and a cathode electrode and a catholyte electrolyte flowing through the second half cell; wherein the first half cell and the second half cell each include a plurality of dividers or barriers which dividers or barriers are configured to create flow channels running essentially the length of the half cells and which to introduce turbulence insuring that the electrolytes are changing or mixing at surfaces of the electrodes and the membrane.

In one preferred aspect the dividers or barriers are configured essentially parallel to one another. In another aspect the dividers or barriers are configured as interdigitized fingers. In yet another aspect, the battery comprises a plurality of half cells arranged parallel to one another. In still yet another aspect, the battery comprises a plurality of half cells arranged in series, with an outlet of a first half cell being connected to an inlet of an adjacent second half cell.

The present disclosure also provides improvements over conventional dual electrode redox flow electrical energy storage battery systems by providing a membrane-less redox flow battery system. The membrane-less flow battery in accordance with the present disclosure includes a high surface area porous silicon electrode. More particularly, in accordance with the present disclosure, silicon substrate material is subjected to an electrochemical etching to form interconnected nano structures or through holes or pores through the silicon substrate material. Surfaces of the porous silicon substrate material are then treated to enhance surface ion conductivity by deposition of a metal, preferably, titanium metal to form titanium silicide on surfaces of the pores of the silicon substrate material. The titanium metal may be deposited on the porous silicon substrate material using various deposition techniques including but not limited to chemical vapor deposition (CVD), plasma-enhanced chemical vapor deposition (PECVD), thermal CVD, electroplating, electroless plating, and/or solution deposition techniques, which are given as exemplary, and the metal-coating on the porous silicon substrate material is converted to the corresponding metal silicide by heating. Tungsten, nickel, cobalt, platinum and palladium metals also may be deposited on the porous silicon substrate material to form the corresponding metal silicide coated electrodes. Another possibility is to deposit amorphous carbon from CH₃.

The resulting substrate is a porous silicon substrate which includes a metallurgically bonded surface layer of metal silicide on the walls of the porous structure, which advantageously may be used as an electrode in a membrane-free redox flow energy storage battery as will be described below.

The present disclosure also provides an electrode for use in a redox flow electrical energy storage battery, wherein the electrode comprises a substrate formed of porous silicon in which surface areas of the pores are coated at least in part with a metal silicide. The silicon substrate may comprise monocrystalline silicon, polycrystalline silicon, or amorphous silicon, the pores preferably have a depth to cross section dimension aspect ratio of ≤50:1, and the metal silicide preferably is selected from the group consisting of titanium silicide and tungsten silicide, although other metal silicides may be used as noted above.

Further features and advantages of the present disclosure will be seen from the following detailed description, wherein like numerals depict like parts, and wherein:

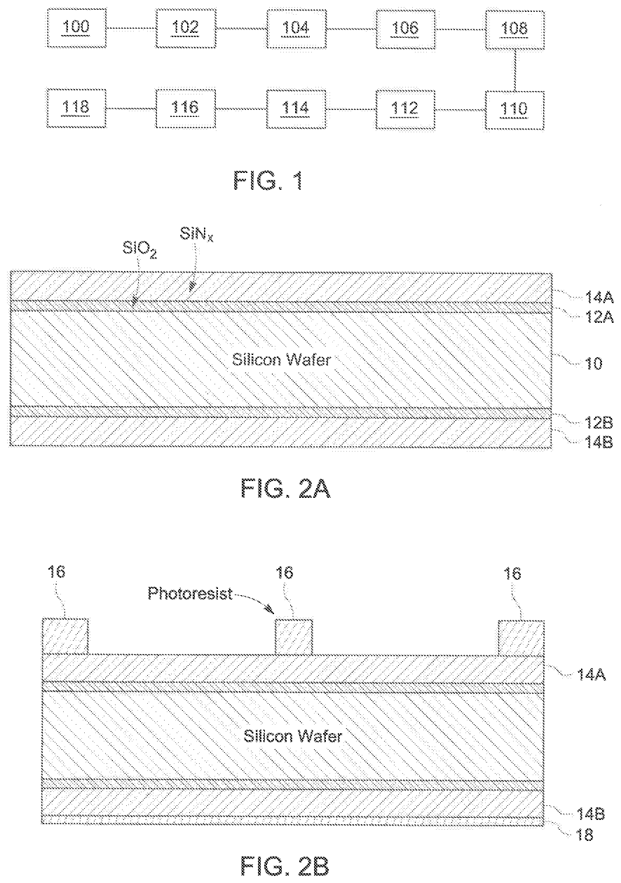

FIG. 1 is a schematic flow diagram showing formation of a porous silicon wafer useful as a membrane in a redox flow battery in accordance with a first embodiment of the present disclosure;

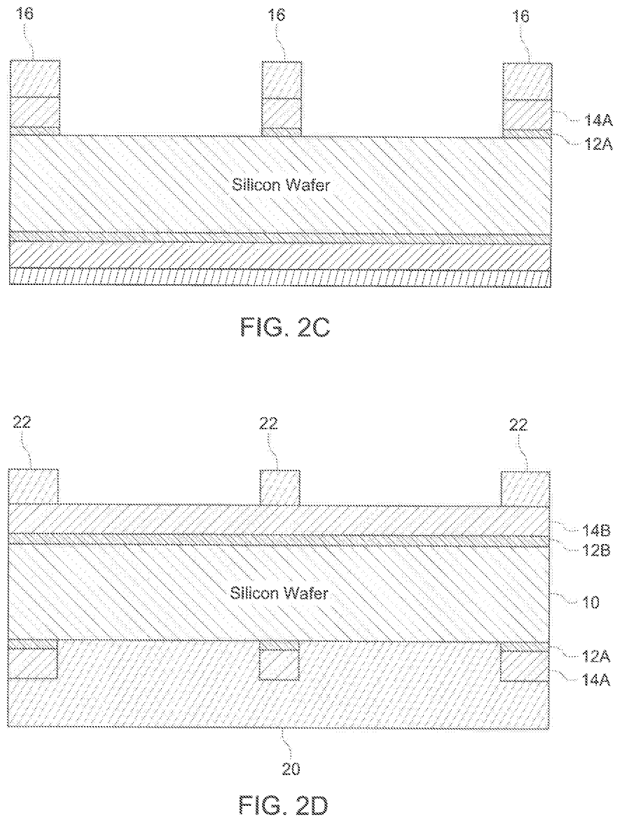

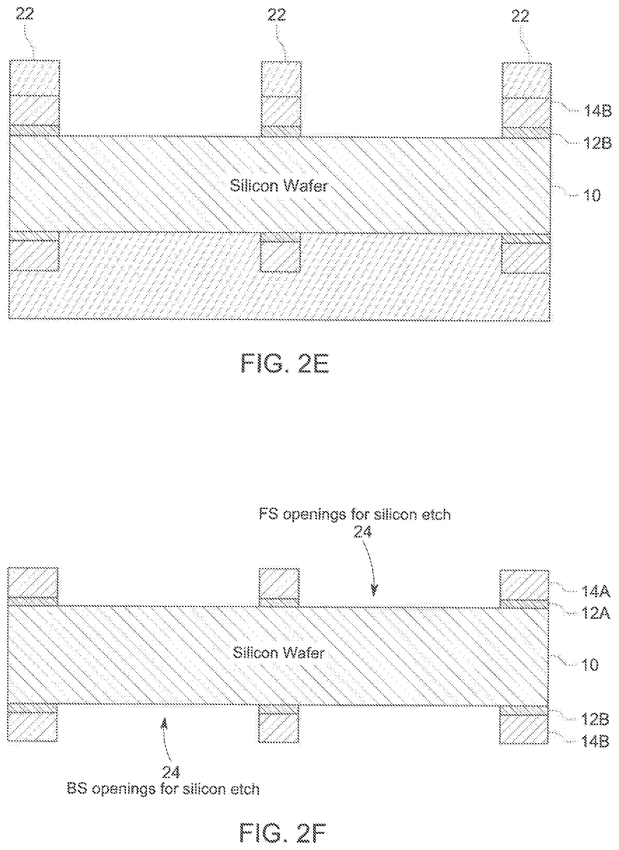

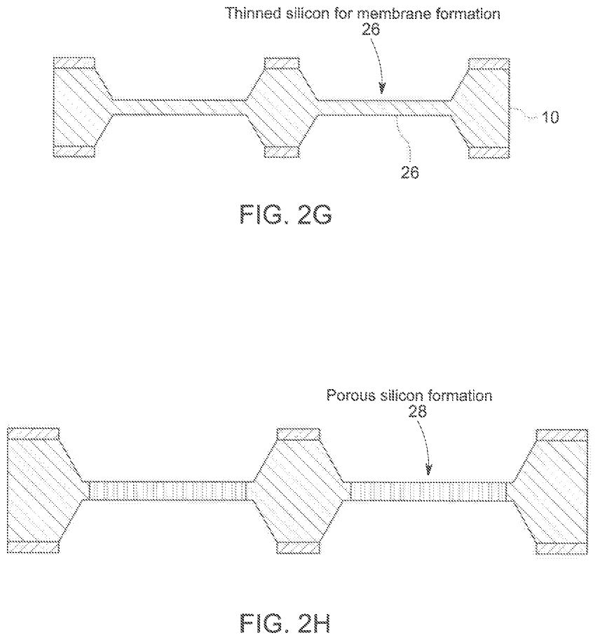

FIGS. 2(a)-2(h) are cross-sectional views illustrating the silicon wafer at various stages of the process of FIG. 1;

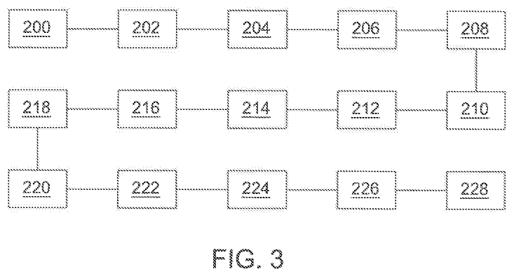

FIG. 3 is a view, similar to FIG. 1, showing an formation of a porous silicon wafer useful as a porous membrane in a redox flow battery in accordance with a second embodiment of the present disclosure;

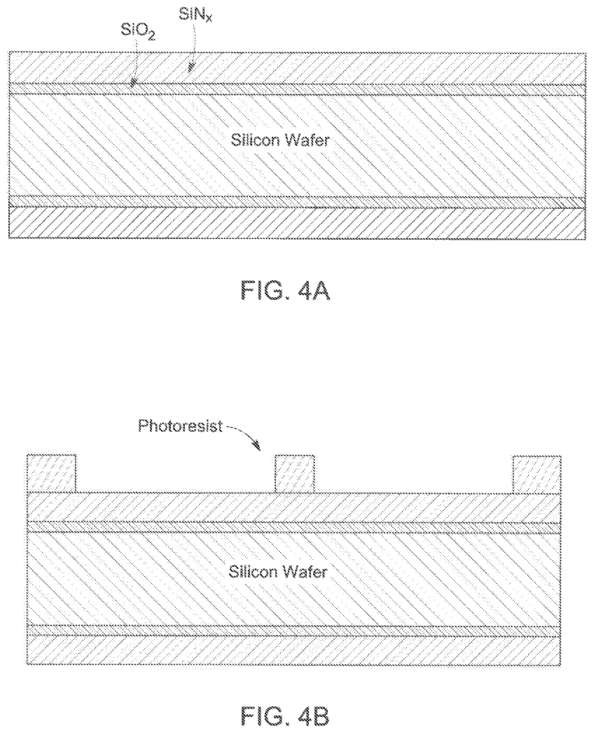

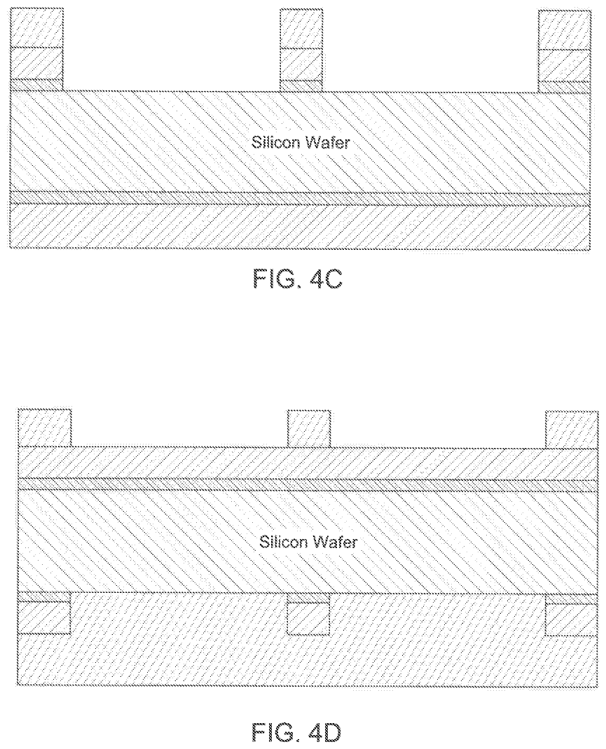

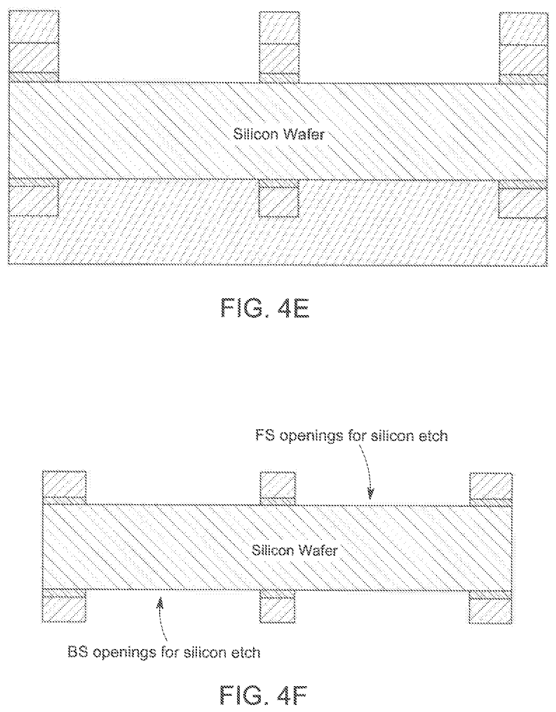

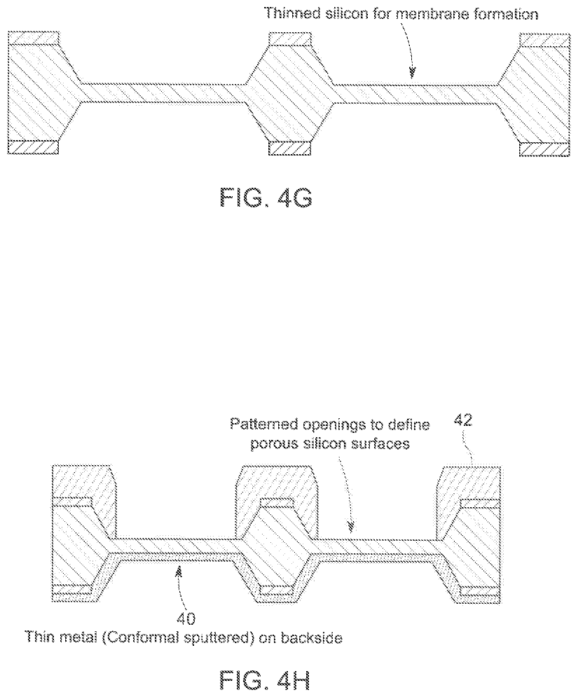

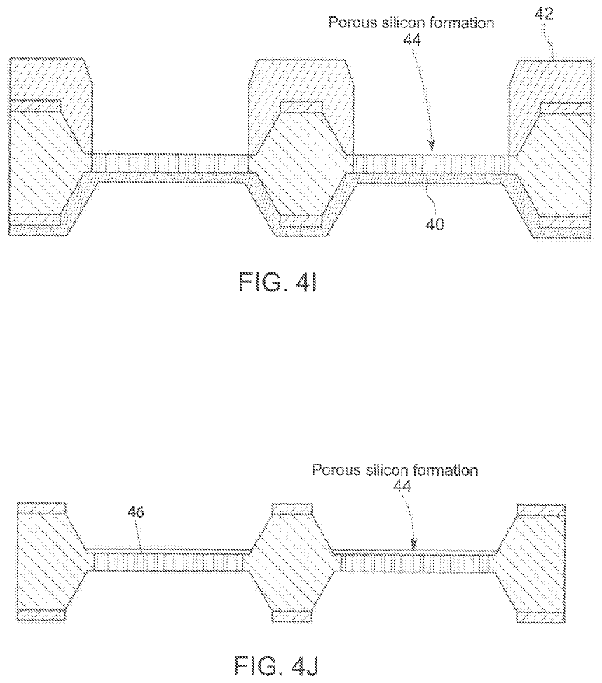

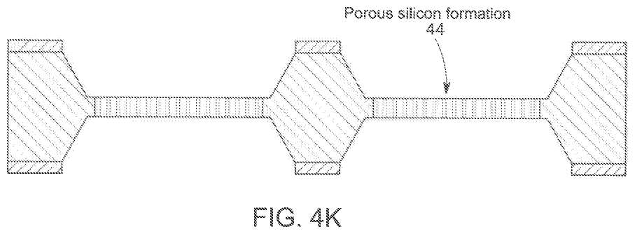

FIG. 4(a)-4(k) are cross-sectional views illustrating the silicon wafer at various stages of the process of FIG. 3;

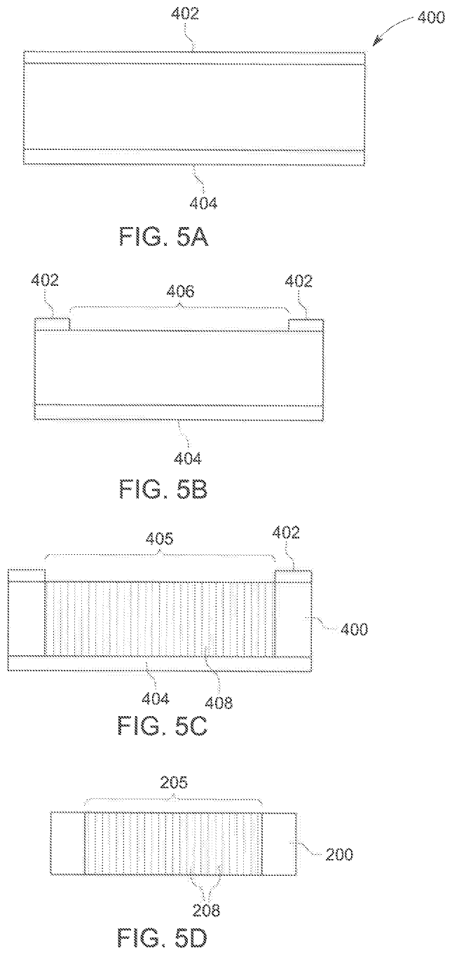

FIGS. 5(a)-5(d) are schematic cross-sectional views showing formation of a porous silicon wafer made in accordance with another embodiment of the present disclosure;

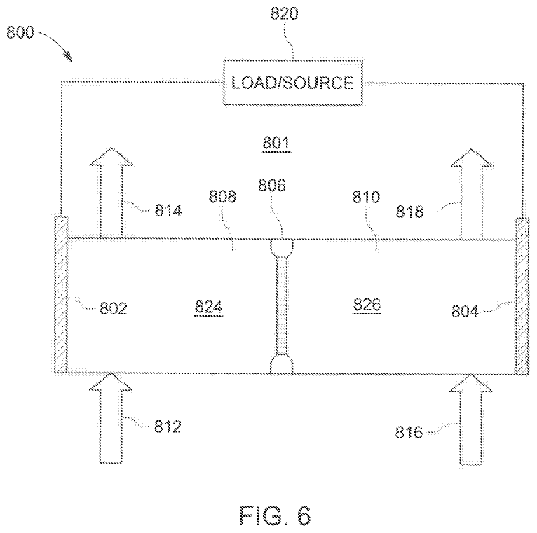

FIG. 6 is a schematic view of a first embodiment of redox flow battery in accordance with the present disclosure;

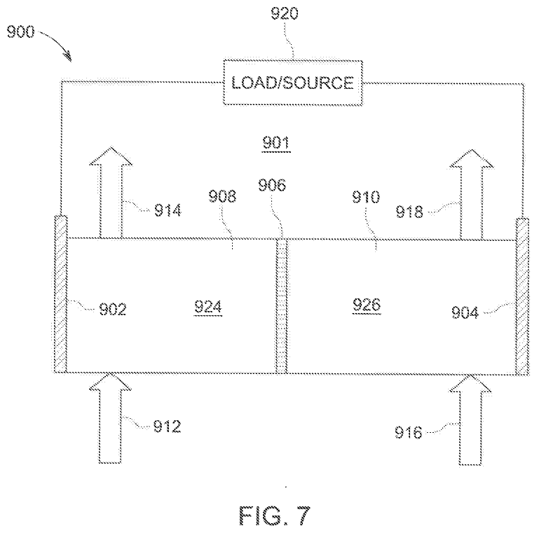

FIG. 7 is a schematic view of a second embodiment of redox flow battery in accordance with the present disclosure;

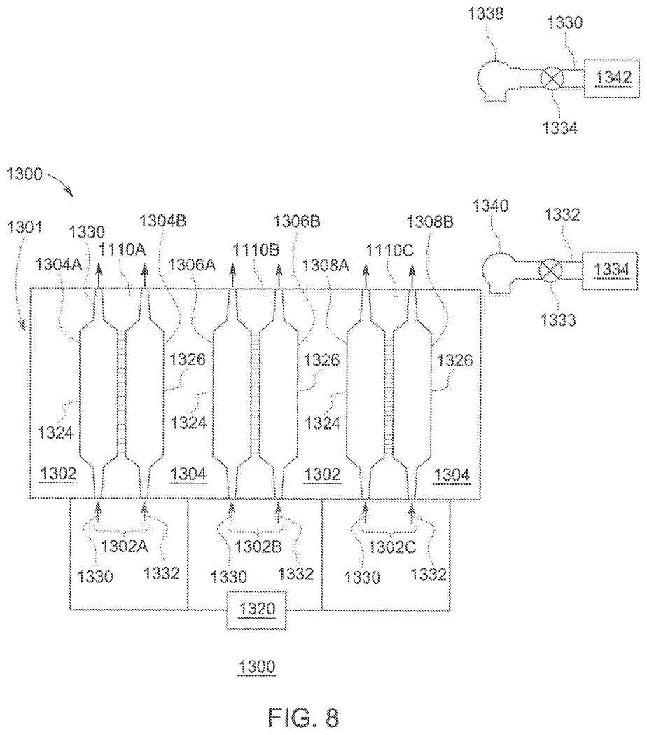

FIG. 8 is a schematic cross-sectional view of a redox flow battery system made in accordance with the present disclosure;

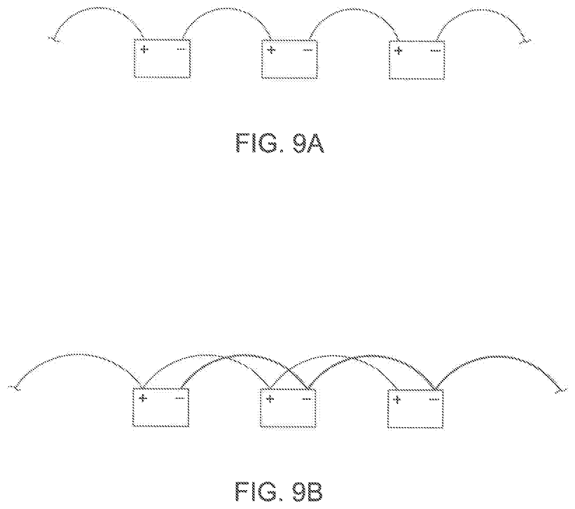

FIGS. 9(a) and 9(b) are schematic cross-sectional views of redox flow battery stacks showing multiple redox flow batteries stacked in series (FIG. 9(a)) and in parallel (FIG. 9(b)), respectively;

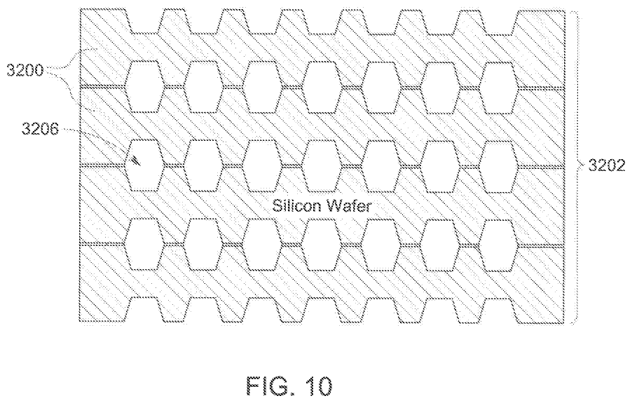

FIG. 10 is a cross-sectional view of a silicon wafer stack made in accordance with the present disclosure, and combined to form micro channels, forming an electrode cell assembly in accordance with the present disclosure;

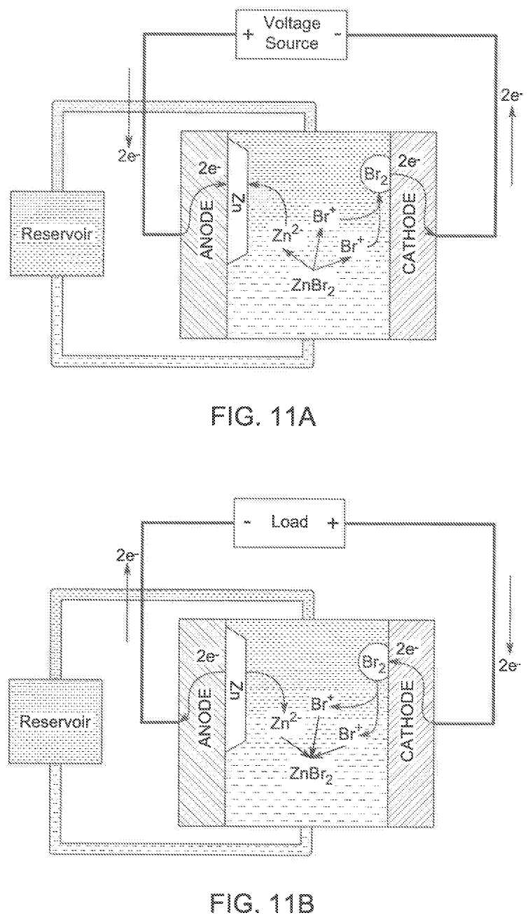

FIGS. 11(a) and 11(b) schematically illustrate operation of a single electrolyte flow loop for a flow battery in accordance with the present disclosure;

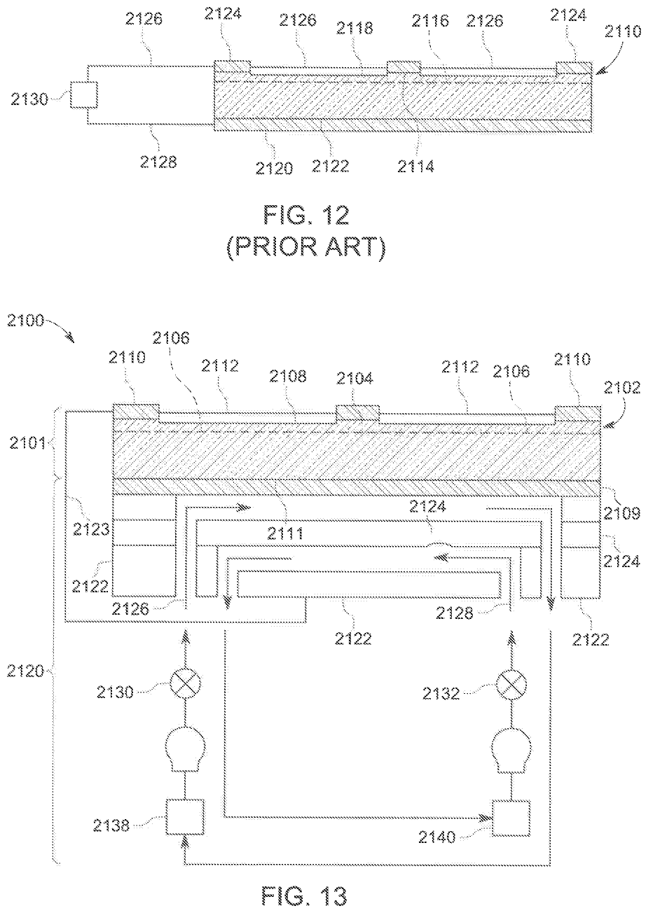

FIG. 12 is a schematic view of a conventional prior art silicon solar cell;

FIG. 13 is a schematic view of a photovoltaic cell having an integrated redox flow battery in accordance with one embodiment of the present disclosure;

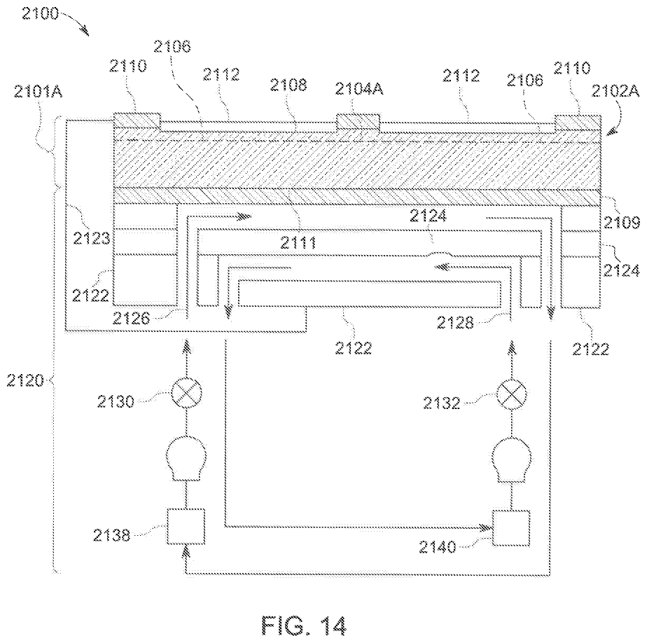

FIG. 14 is a schematic view of a photovoltaic cell having an integrated redox flow battery in accordance with another embodiment of the present disclosure;

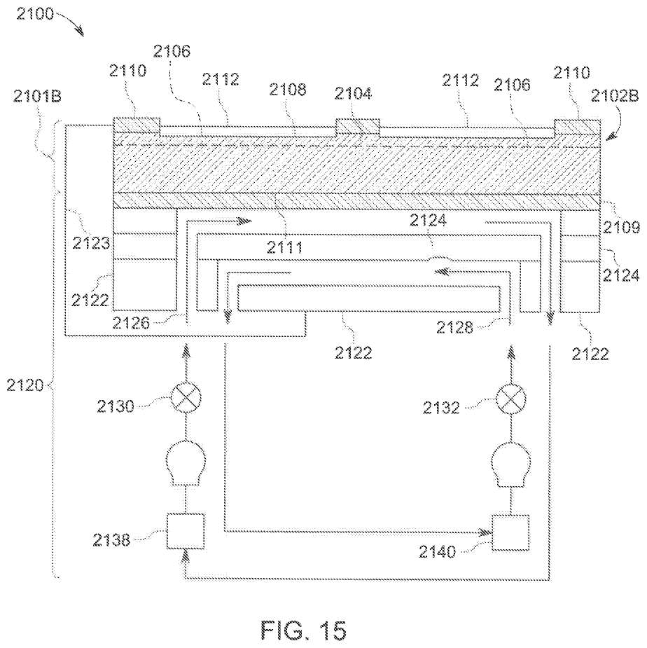

FIG. 15 is a schematic view of a photovoltaic cell having an integrated redox flow battery in accordance with yet another embodiment of the present disclosure;

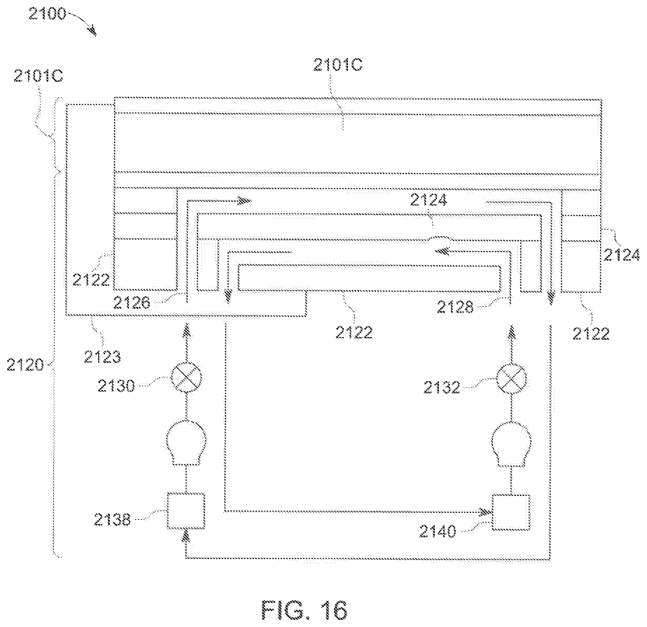

FIG. 16 is a schematic view of a photovoltaic cell having an integrated redox flow battery in accordance with still yet another embodiment of the present disclosure;

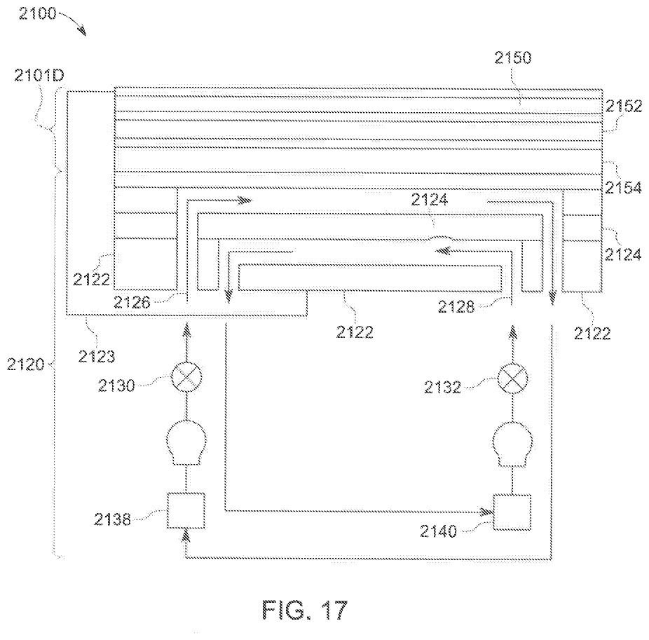

FIG. 17 is a schematic view of a photovoltaic cell having an integrated redox flow battery in accordance with yet another embodiment of the present disclosure;

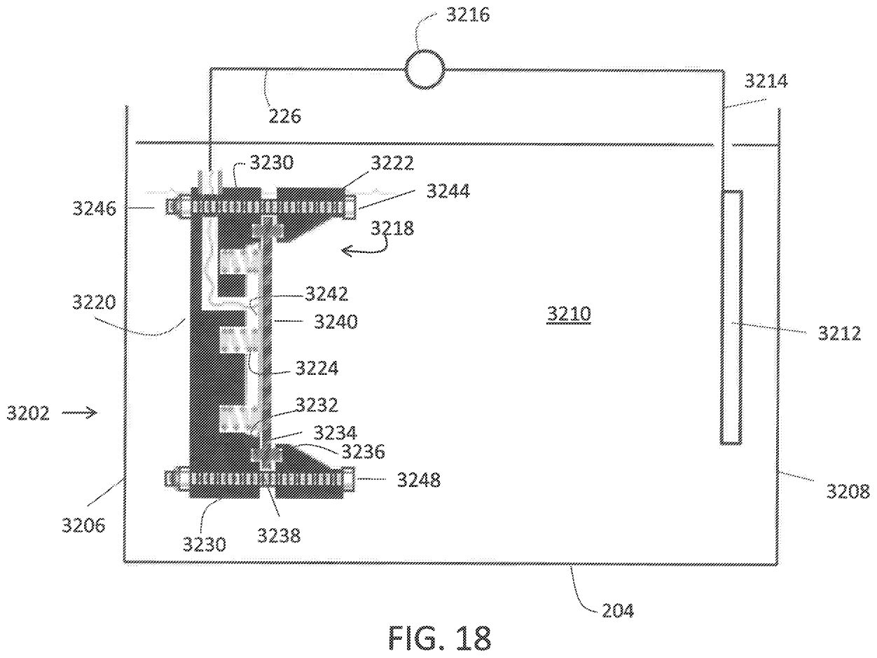

FIG. 18 is a cross-sectional view of an open electrochemical etch fixture in accordance with one embodiment of the present disclosure;

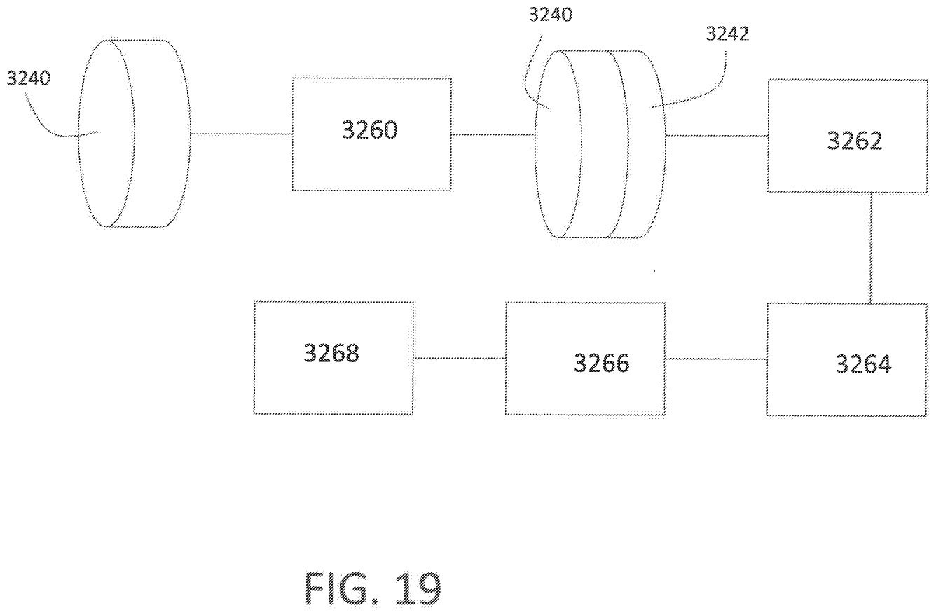

FIG. 19 is a schematic flow diagram of an electrochemical etching process in accordance with one embodiment of the present disclosure;

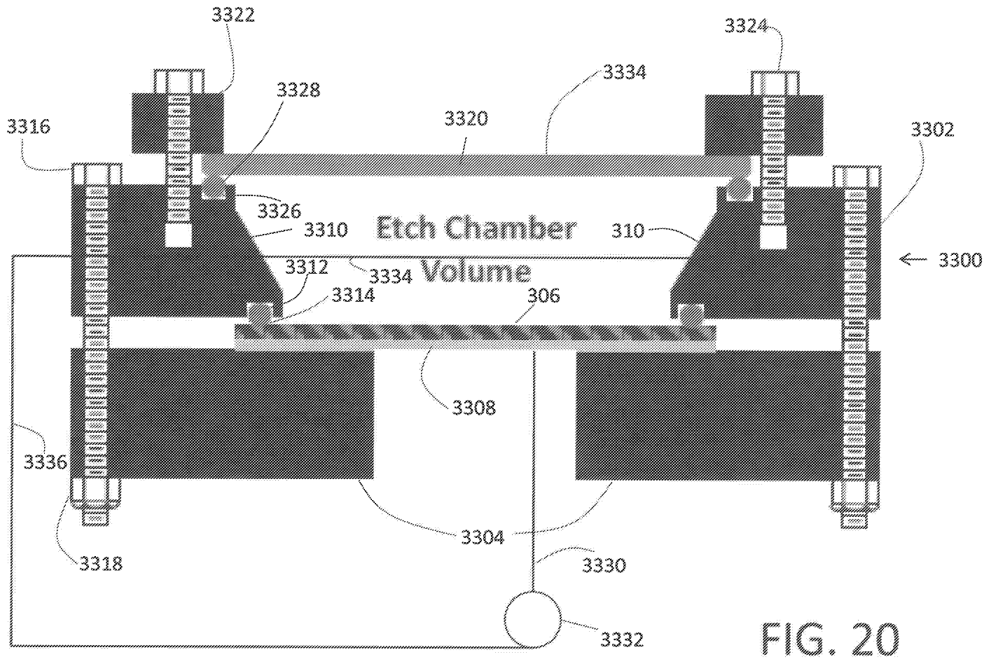

FIG. 20 is a view similar to FIG. 18, of a closed electrochemical etch fixture in accordance with a second embodiment of the present disclosure; and

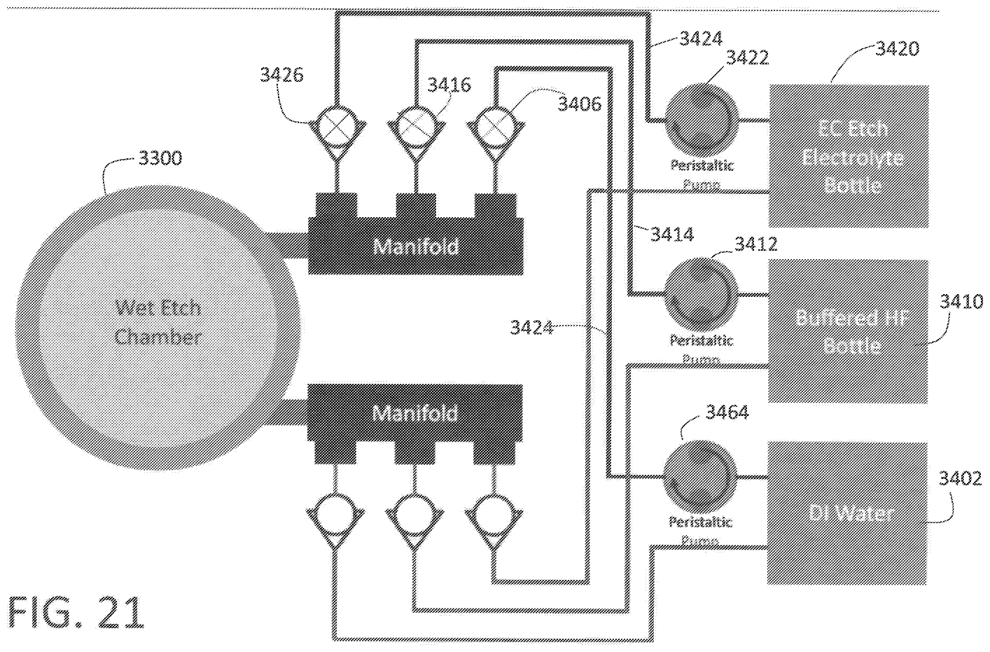

FIG. 21 is a schematic view of an electrochemical etching system in accordance with another embodiment of the present disclosure.

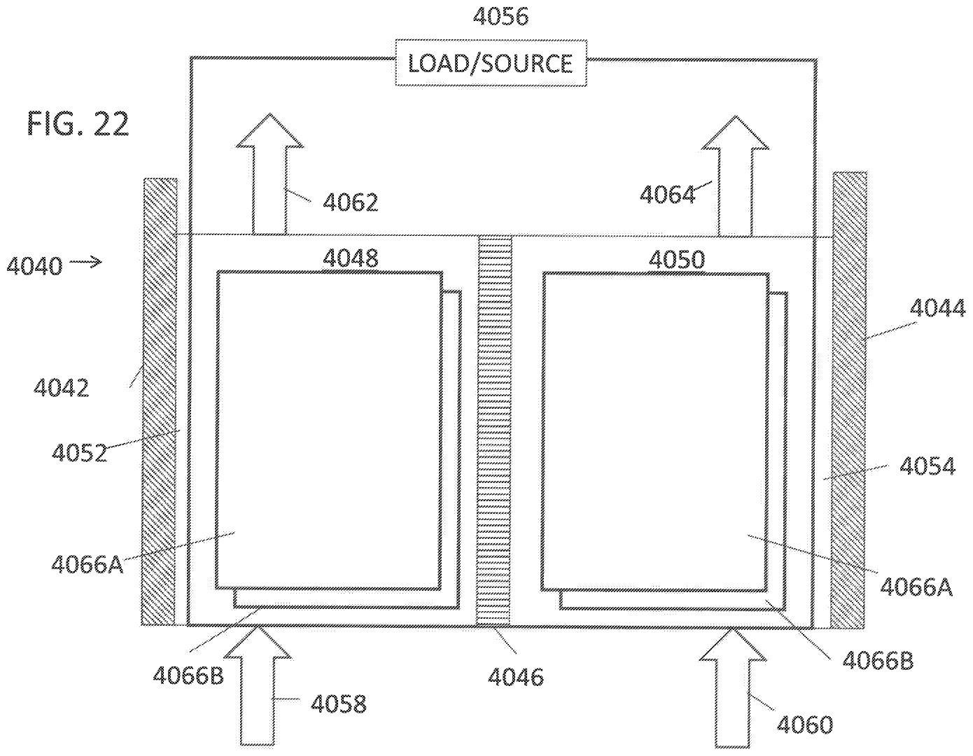

FIG. 22 is a top plan view in partial cross-sectional view of a redox flow electrical energy storage battery in accordance with yet another embodiment of the present disclosure;

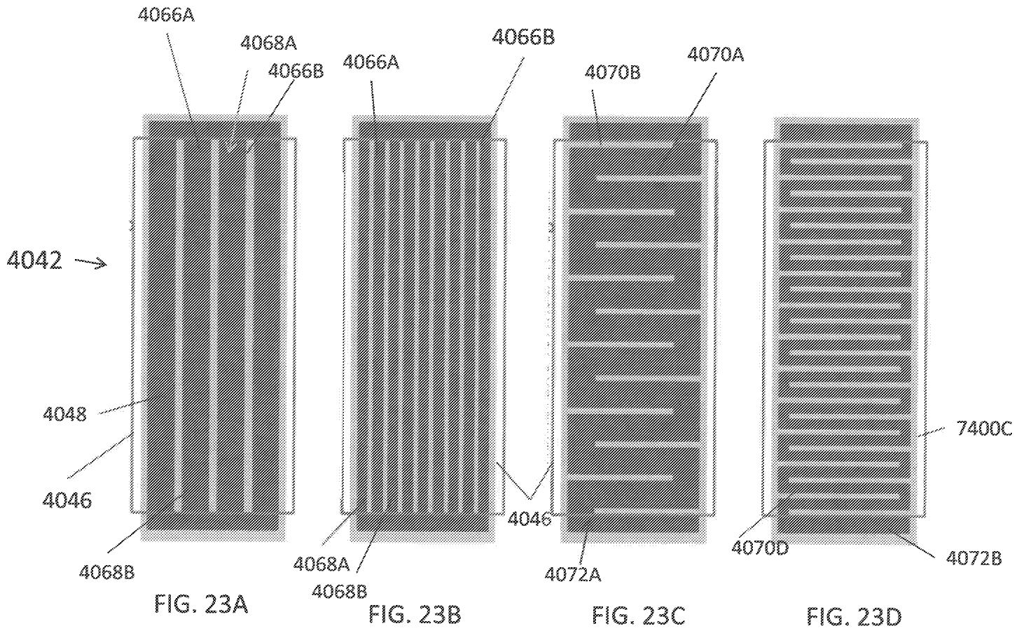

FIG. 23A is a cross-sectional view a half cell of the redox flow electrical energy storage battery cell of FIG. 22;

FIG. 23B is a view similar to FIG. 23A of a variation of a redox flow electrical energy storage battery cell in accordance with the present disclosure;

FIGS. 23C and 23D are views similar to FIG. 23A and FIG. 23B showing yet other variations of redox flow electrical energy redox flow battery cells in accordance with the present disclosure; and

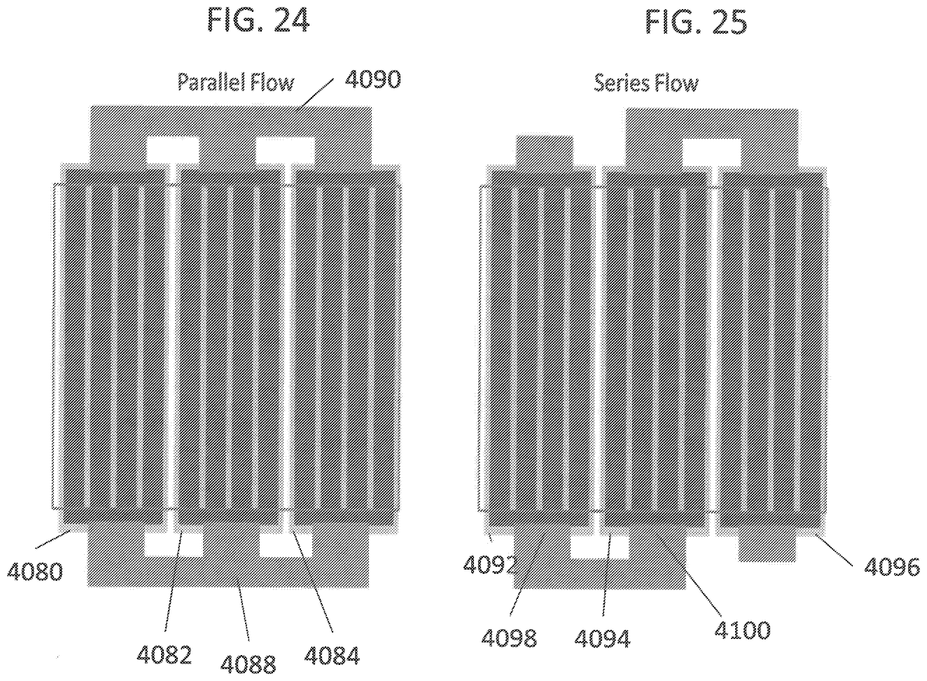

FIGS. 24 and 25 are views similar to FIG. 23A illustrating still yet other variations of redox flow electrical energy storage battery cells in accordance with the present disclosure.

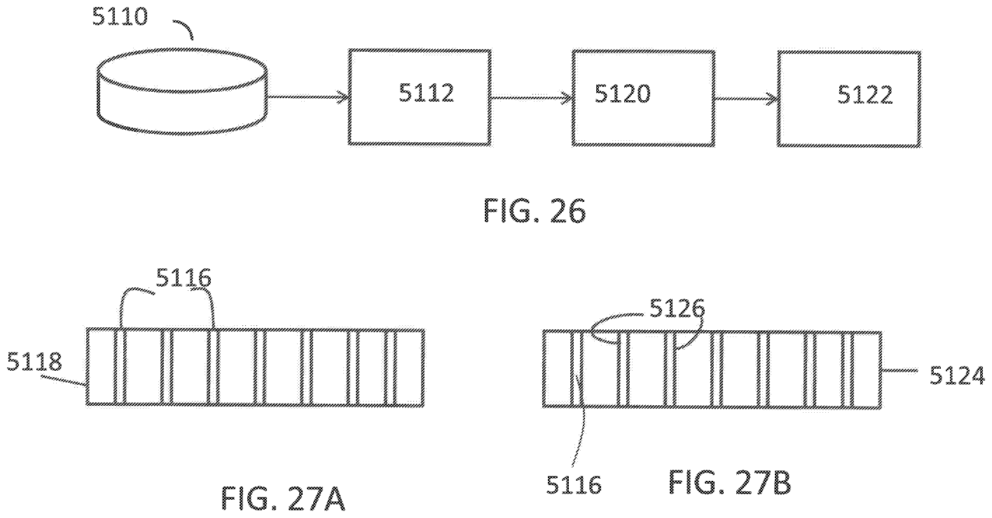

FIG. 26 is a schematic block diagram with a process for producing porous electrode material for use in forming an electrode for use in a membrane-less redox flow energy storage battery in accordance with one embodiment of the present disclosure;

FIGS. 27A and 27B are cross-sectional view of the porous electrode material of FIG. 26 at various stages of production in accordance with the present disclosure;

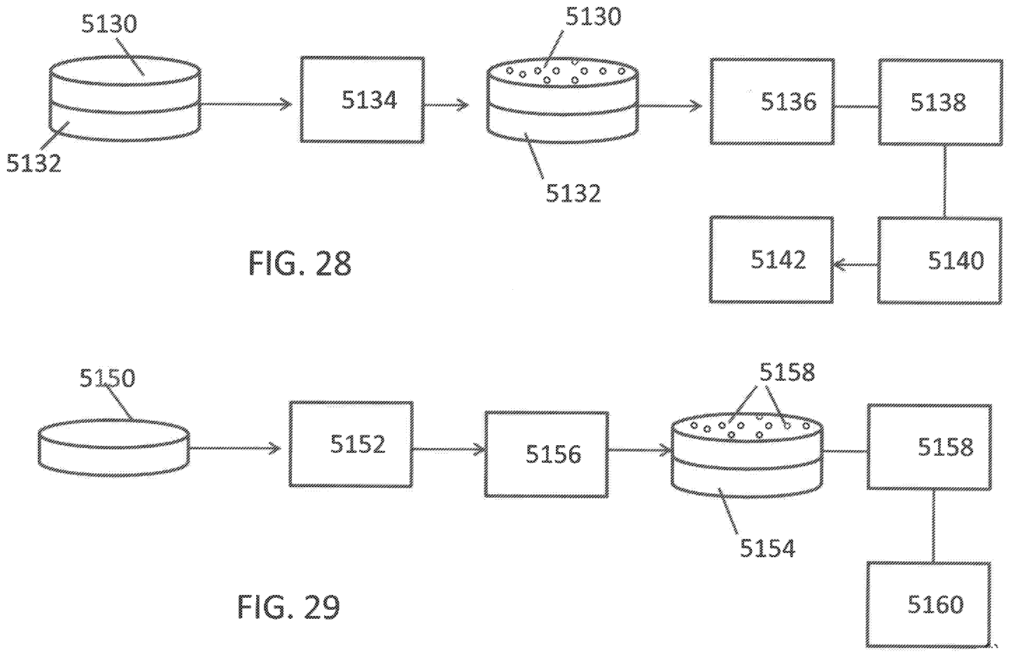

FIG. 28 is a schematic block diagram of a process for producing porous electrode material for use in a membrane-less redox flow electrical energy storage battery in accordance with another embodiment of the present disclosure;

FIG. 29 is a schematic block diagram of a yet another process for producing porous electrode material for use in a membrane-less redox flow electrical energy storage battery in accordance with the present disclosure;

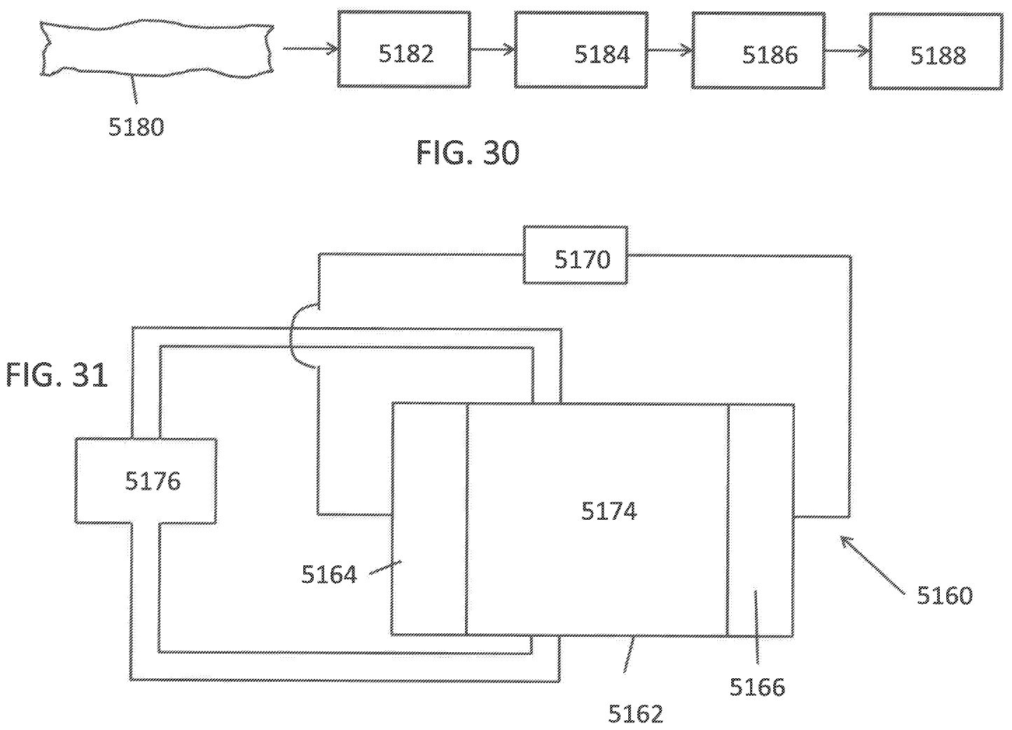

FIG. 30 is a schematic block diagram of still yet another process for producing porous electrode material for use in a membrane-less redox flow electrical energy storage battery in accordance with the present disclosure;

FIG. 31 is a cross-sectional view of a rechargeable battery in accordance with the present invention;

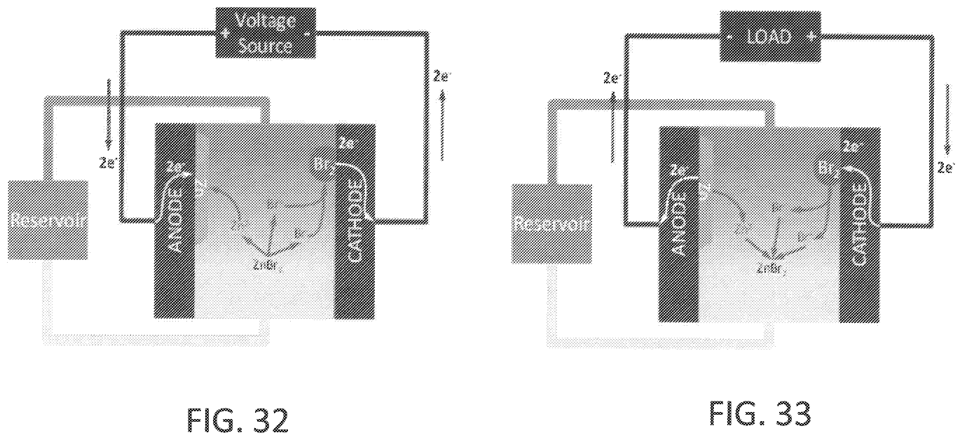

FIGS. 32 and 33 are schematic views showing operation of a membrane-less redox flow energy storage battery of FIG. 31 in accordance with the present disclosure; and

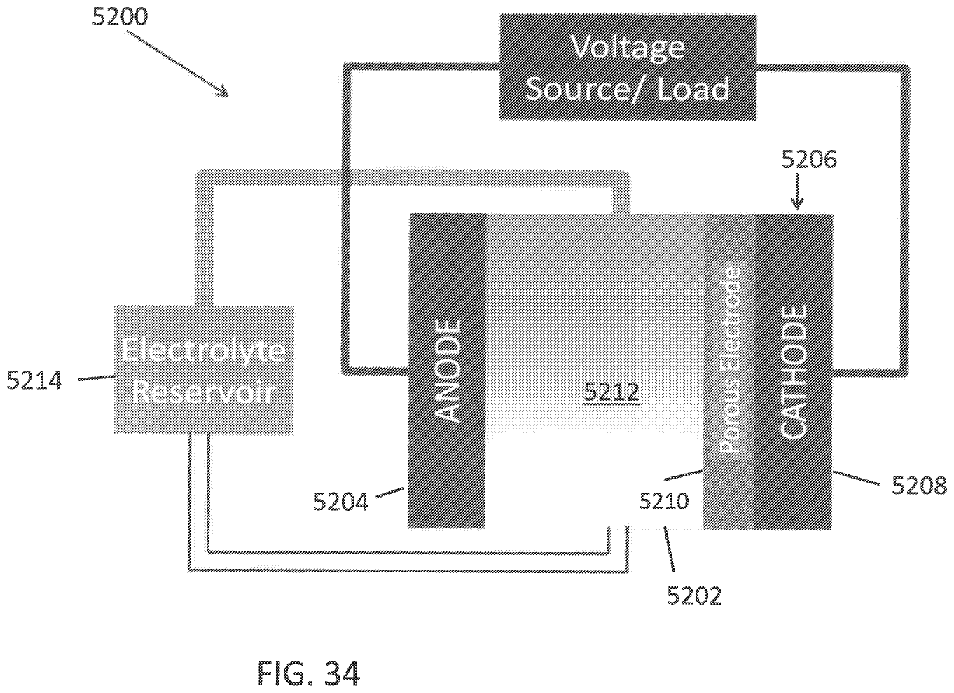

FIG. 34 is a view similar to FIG. 31, of an alternative form of a membrane-less redox flow battery in accordance with the present disclosure.

Modes for carrying out the present disclosure will be described in detail below, with reference to the drawings.

### FIRST EMBODIMENT

FIGS. 1 and 2(a)-2(h) are schematic and cross-sectional views showing the steps of manufacturing a porous silicon wafer according to a first embodiment of the present disclosure. In the drawings the cross-sectional dimension of the pores in the horizontal direction of the drawings figures are shown enlarged for clarity.

Referring to FIGS. 1 and 2(a)-2(h), starting with a silicon wafer 10, as shown in FIG. 2(a), dielectric materials are deposited in step 100 to form a hard mask on front and back sides of the wafer 10. In this case each side of the wafer will first be deposited with 50 nm layer 12a, 12b of SiO₂ followed by 300 nm layers 14a, 14b of SiNₓ.

Next, in step 102, the front side mask 14a is patterned with a photoresist 16 which is spun and patterned on the front side of the wafer, and a polymer material 18 is spun onto the back side of the wafer. Pattern 16 defines the hard mask etch which will in turn be used for a deep anisotropic etch. Alignment elements (not shown) for a subsequent backside etch are also formed at this step 102.

FIG. 2(c) shows a cross section of the wafer after the etch of the pad hardmask (step 104). Here a dry etch (plasma) is used to control the edges of the hardmask to ensure uniform edge erosion during potassium hydroxide (KOH) etch. Alternatively, a tetramethylammonium hydroxide (TMAH) etchant could be used.

As shown in FIG. 2(d), the front side of the wafer is spun with a polymer 20 at step 106 to protect the pattern on the front side while the pad structure on the back side is patterned at 22 in step 108. Alternatively, a back side hardmask could be deposited after the patterning of the front side. The back side pattern 22 is aligned to marks (not shown) formed on the front side of the wafer to ensure they are aligned.

After the back side pad structures are patterned at step 108, a dry etch (plasma) is used in step 110 to etch the dielectrics while controlling the edge shape. This is shown in FIG. 2(e).

FIG. 2(e) shows the nitride (PAD) etch of the back side pad structure, which is aligned to the front side pattern. This step is followed by a resist strip and wafer clean step 112 in preparation for wet etch of features.

FIG. 2(f) shows the configuration of the wafer after the resist strip and before KOH or other anisotropic etch in step 114. We prefer to use a wet etch so that both faces can be etched simultaneously to ensure the same etch depth on both sides. However, a plasma etch could be used to independently etch each face. The open areas 24 as delineated by the etching of the dielectrics are shown on each side of the wafer.

The next step 116 is to etch the silicon to thin it locally to create regions 26 for defining thinner silicon regions for formation of the porous silicon material in a subsequent step 118 as will be described below. This step preferably is conducted using a simple open bath etch, although a tool etch could be used. FIG. 2(g) shows the wafer after anisotropic wet etch 116.

The thinned or contoured silicon wafer from step 116, is then subjected to an electrochemical etching by applying uniform electrical field across the wafer while immersing the wafer in an etchant such a Dimethylformamide (DMF)/Dimethylsulfoxide (DMSO)/HF etchant in an electrochemical immersion cell, in an electrochemical etching step 118, to form through holes or pores 28 through the thinned section 26 as shown in FIG. 2(h). Alternatively, hydrogen fluoride etchant may be used. The growth of well-defined cylindrical micropores or through holes can be controlled by controlling etching conditions, i.e., etching current density, etchant concentration, temperature, silicon doping, etc., following the teachings of Santos et al., Electrochemically Engineered Nanoporous Material, Springer Series in Materials Science 220 (2015), Chapter 1, (ISBN 978-3-319-20346-1), the contents of which are incorporated herein by reference.

The resulting pores have a high aspect ratio of length to cross-sectional diameter typically a depth to cross section dimension aspect ratio of ≤50:1. The resulting structure, shown in FIG. 2(h) comprises a porous silicon wafer 30 having substantially cylindrical through holes or pores 28 having a length of, e.g., 180 nm and a diameter of 1.6 nm, i.e, an aspect ratio of 112.5:1 which is quite effective for use as a separator barrier in a redox flow battery as will be described below. The resulting porous silicon wafer 30 may then be incorporated as a membrane in a redox flow battery as will be described below.

### SECOND EMBODIMENT

FIGS. 3-4 illustrate a second embodiment of the present disclosure. The process steps 200-216 of FIG. 3, and cross-sectional views of FIGS. 4(a)-4(g) are identical to process steps 100-116 of FIG. 1 and cross-sectional views 2(a)-2(g) above described.

However, referring to FIG. 4(h) upon completion of contouring etch step 216, we put a thin metal layer 40 on the back side of the contoured wafer e.g., by sputtering in a step 218 followed by a photolithographing resist step 220 on the front side of the contouring wafer. Metal layer 40 on the backside of the wafer promotes improved electrical contact to the wafer, while the resist 42 applied in the photolithography step 220 limits porous silicon formation to the thinned region 26 of silicon in the following etching step described below.

As shown in FIG. 4(i), an electro chemical etching (step 222) is used to form porous silicon 44 within the areas unprotected by the resist 42.

After porous silicon formation, step 222, the front side is protected by spinning a photoresist 46 on it in step 224 (see FIG. 4(j)) and a wet etch (step 226) is used to remove the thin metal 40 from the back side. The front side resist 46 is then striped in a resist stripping step 228. FIG. 4(k) shows the final configuration after metal etch and photoresist strip. Optionally, an additive process such as atomic layer deposition may be used to modify the surface of the pores or the pore diameters, before the stripping step 228.

### THIRD EMBODIMENT

FIGS. 5-6 illustrate a third embodiment of the present disclosure. The process starts with a silicon wafer 400 covered on one side with a resist layer 402, and covered on the opposite side by a sacrificial metal layer 404 formed of, for example, a noble metal such as platinum. Palladium also may be used as the sacrificial metal layer. (see step FIG. 5(a)). The resist layer 402 is patterned at step 502, and etched at step 504 to expose a selected surface 406 one side of the wafer 400 (FIG. 5(b)). The resist covered and patterned wafer is then subjected to electrochemical etching by applying an uniform electrical field across the metal layer 404 and substrate wafer 400 as the wafer is immersed in an electrochemical cell containing an etchant such as HF and H₂O₂, in step 506, whereby to produce substantially uniform pores 408 through the exposed portion of the substrate 400 to the metal layer 404 (FIG. 5(c)). As before, the growth of well-defined cylindrical micropores with two holes can be controlled by controlling etching conditions, i.e., etching current density, etching concentration, temperature, silicon doping, etc., again following the teachings of Santos et al. Alternatively, micropore or through hole formation can be controlled by covering selected portions of the silicon wafer with a nanoporous anodic alumina mask. Self-ordered nano porous anodic alumina is basically a nanoporous matrix based on alumina that features closed-packed arrays of hexagonally arranged cells, at the center of which a cylindrical nanopore grows perpendicularly to the underlying aluminum substrate. Nanoporous anodic alumina may be produced by electrochemical anodization of aluminum, again following the teachings of Santos et al. the teachings of which are incorporated herein by reference. The resist layers 402 and sacrificial metal layer 404 can then be removed in a step 508 leaving a porous silicon wafer having a section 405 having substantially cylindrical through holes or pores 408 (FIG. 5) which may then be incorporated as a membrane in a redox flow battery as will be described below. As before, there results a porous silicon wafer having substantially cylindrical though holes or pores having a depth to cross section dimension aspect ratio of ≤50:1.

The porous silicon wafers as produced above are assembled into a redox flow battery as will be described below.

Battery Formation

FIG. 6 is a cross-sectional view of a first embodiment of a redox flow battery made in accordance with the present disclosure. As shown, redox flow cell system includes redox flow cell stack 801. For convenience of illustration, stack 801 is represented by a single flow cell, which includes two half-cells 808 and 810 separated by a membrane 806 made according to FIGS. 1-3. Typically, stack 801 will include a plurality of single flow cells. An electrolyte 824 such as an iron-ligand electrolyte is flowed through half-cell 808 and an electrolyte 826 is flowed through half-cell 810. Half-cells 808 and 810 include electrodes 802 and 804, respectively, in contact with electrolytes 824 and 826, respectively, such that redox reactions occur at the surface of the electrodes 802 or 804 according to the reactions set forth in Table I, below.

In some embodiments, multiple redox flow cells are electrically coupled (e.g., stacked) either in series to achieve higher voltage or in parallel in order to achieve higher current to form stack 801. The stacked cells are collectively referred to as a battery stack and flow cell battery can refer to a single cell or battery stack. As shown in FIG. 6, electrodes 802 and 804 are coupled across load/source 820, through which electrolytes 824 and 826 are either charged or discharged.

When filled with electrolyte, half-cell 310 of redox flow cell 800 contains anolyte 826 and the other half-cell 808 contains catholyte 824, the anolyte and catholyte being collectively referred to as electrolytes. Reactant electrolytes may be stored in separate reservoirs and dispensed into half-cells 808 and 810 via conduits coupled to cell inlet/outlet (I/O) pipes 812, 814 and 816, 818 respectively. In some embodiments, an external pumping system is used to transport the electrolytes to and from the redox flow cell. Electrolyte 824 flows into half-cell 808 through inlet pipe 812 and out through outlet pipe 814, while electrolyte 826 flows into half-cell 810 through inlet pipe 816 and out of half-cell 810 through outlet pipe 818.

At least one electrode 802 and 804 in each half-cell 808 and 810 provides a surface on which the redox reaction takes place and from which charge is transferred. Suitable materials for preparing electrodes 802 and 804 generally include those known to persons of ordinary skill in the art. Redox flow cell 800 operates by changing the oxidation state of its constituents during charging or discharging. The two half-cells 808 and 810 are connected in series by the conductive electrolytes, one for anodic reaction and the other for cathodic reaction. In operation (e.g., during charge or discharge), electrolytes 826 and 824 are flowed through half-cells 308 and 810 through inlet/outlet pipes 812, 814 and 816, 818 respectively as the redox reaction takes place.

Positive ions or negative ions pass through permeable membrane 806, which separates the two half-cells 808 and 810, as the redox flow cell system 800 charges or discharges. Reactant electrolytes are flowed through half-cells 808 and 810, as necessary, in a controlled manner to supply electrical power or be charged by load/source 820.

A feature and advantage of the present disclosure derives from the size and aspect ratio of the pores or through holes of the membrane. Within the pores, which can be treated as an array of regular cylindrical ion channels, the ionic current can be described as:

Iᵢₒₙ=(KA+K^{σ}p)E

where E is the tangential electric field parallel to the channel walls, K is the bulk conductivity, K^{σ} is the surface conductivity, A is the round pore channel cross sectional area and p is the cross sectional perimeter. The ionic current has a bulk convective component which is proportional to ion mobility μ and electrolyte concentration n. In specific embodiments, the length of the pore will be 50 times or more greater than the diameter of the pores. As such, the second term in the above equation will dominate in most cases as applied. The resulting material can be modified for use in redox flow batteries to enhance the surface ion conductivity to allow optimization of the ion current. The ability to also tune the geometry of the porous silicon channels allow control of the separation of electrolytes or other fluids while providing a path for ions to flow in the presence of an electric field. By comparison to standard flow battery configurations the separation of electrodes may be reduced from millimeters to microns. Also we can modify the surfaces of these channels to enhance the transport of specific cation or anion species, and control the separation of fluids having a wide range of viscosities. These modifications include everything from the oxidation of the surface to create deep silicon dioxide surfaces, or through various vapor based deposition methods to add a metal layer, e.g., tungsten, nickel, platinum or palladium, which are given as exemplary, to modify the ion mobility.

By comparison to prior art approaches, such as membranes formed of Nafion®, the high porosity of porous silicon wafer and very large surface-to-volume ratio ensures high proton/ion conductivity, comparable with or in excess of that of polymer membranes employing the standard Nafion® materials, and at a fraction of the cost. The ability to control the transport behavior of ions is another important capability as it allows the shaped porous silicon wafer to be employed in a wide range of applications, from fuel cell and flow battery to chemical synthesis and separation.

As noted supra, our process also allows for functionalization of the membrane. The fluid interfaces on each side of the membrane can be coated with catalytic materials to enhance and control the interaction with the electrolyte chemistry. And, metal deposition technologies can be used to form electrodes at the interfaces of the porous silicon material, further reducing separation and increasing field density, and in the case of fuel cells and flow batteries enhancing the overall efficiency of the ion transport (e.g., stronger field; reduced ion travel length.) FIG. 7 is a cross-sectional view of another embodiment of redox flow battery 900 made in accordance with the present disclosure. The redox flow battery 900 is similar to the redox flow battery 800 of FIG. 6; however, in the case of FIG. 6, membrane 806 is replaced with a membrane 900 formed according to FIGS. 5(a)-5(d), and the electrolyte 924, 926 is an iron-chloride (FeCl₃) electrolyte, resulting in reactions as will be described below.

FIG. 8 is a cross-sectional view of another embodiment of a redox flow battery system 1300 made in accordance with the present disclosure. As shown, redox flow cell system includes a plurality of paired half-cells in a stack 1301. For convenience of illustration, stack 1301 is represented by three flow cells 1302A, B, C each of which includes two half-cells 1304A/B, 1306A/B, 1308A/B separated by contoured porous silicon wafers 1110A/B/C made as described above. Typically, stack 1301 will include a plurality (2, 3, 4 or more) paired half-cells. An electrolyte 1324 such as an iron-ligand electrolyte is flowed through half-cells 1304A, 1306A, 1308A and an electrolyte 1326 is flowed through half-cells 1304A, 1304B, 1304C. Half-cells 1304A/B, 1306A/B, 1308A/B are bordered on their sides opposite the contoured wafers 1110A/B/C by current collectors or electrodes 1302 and 1304, respectively. Electrodes 1302 and 1304, in turn are in contact with electrolytes 1324 and 1326, respectively which are introduced into and flowed through half-cells 1304A/B, 1306A/B and 1308A/B via conduits 1330, 1332, valves 1334, 1336 and pumps 1338, 1340 to and from electrolyte reservoirs 1342, 1344, such that redox reactions occur at the surface of the electrodes 1302 or 1304 according to the reactions described in Table I below:

TABLE I

| | | | Discharge |
|---|---|---|---|
| | Positive/Anode/Redox | Negative/Cathode/Plating | Energy Density |
| Description | electrode Reaction | electrode Reaction | (Watt*hour/liter) |
| Iron-ligand | 2Fe²⁺ ⇔ Fe³⁺ + | Fe²⁺ + 2e⁻ ⇔ | 3/30 |
| chemistry redox | 2e⁻ (+0.77 V) | Fe⁰ (−0.44 V) | |
| flow batteries | | | |

In some embodiments, multiple redox flow cells are electrically coupled (e.g., stacked) either in series (FIG. 9(a)) to achieve higher voltage or in parallel (FIG. 9(b)) in order to achieve higher current from stack 301. The stacked cells are collectively referred to as a battery stack and flow cell battery can refer to a single cell or battery stack. As shown in FIG. 8, electrodes 1302 and 1304 are coupled across load/source 1320, through which electrolytes 1324 and 1326 are either charged or discharged.

When filled with electrolyte, half-cells 1304A, 1306A, 1308A contain anolyte 1326 and the other half-cells 1304B, 1306B, 1308B contain catholyte 1324, the anolyte and catholyte being collectively referred to as electrolytes. Reactant electrolytes may be stored in separate reservoirs 1342, 1344 and flowed into half-cells 1304A/B, 1306A/B, 1308A/B via conduits 1330, 1332 coupled to half cell inlet/outlets, respectively. In some embodiments, an external pumping system is used to transport the electrolytes to and from the redox flow cells. Electrolyte 1324 flows into and out of half-cells 1308A/B/C through conduits 1330, while electrolyte 1326 flows into and out of half-cells 1304B, 1306B, 1308B through conduit 1332.

At least one current collector or electrode 1302 and 1304 in each half-cell 1304A, 1306A, 1308A and 1304B, 1306B, 1308B provides a surface on which the redox reaction takes place and from which charge is transferred. Suitable materials for forming electrodes 1302 and 1304 generally include those known to persons of ordinary skill in the art. Redox flow battery 1300 operates by changing the oxidation state of its constituents during charging or discharging. The two half-cells 1304A, 1306A, 1308A and 1304B, 1306B, 1308B are connected in series by the conductive electrolytes, one for anodic reaction and the other for cathodic reaction. In operation (e.g., during charge or discharge), electrolytes 1326 and 1324 are flowed through half-cells 1304A, 1306A, 1308A and 1304B, 1306B, 1308B through conduits 1330, 1332 to the inlets/outlets of the half-cells 1304A, 1306A, 1308A, as the redox reaction takes place.

Positive ions or negative ions pass through thinned or porous sections 1104 of the contoured wafers 1110A/B/C, which separates the two half-cells 1304A, 1306A, 1308A and 1304B, 1306B, 1308B, as the redox flow cell battery 1300 charges or discharges. Reactant electrolytes are flowed through half-cells 1304A/B, 1306A/B, 1308A/B, as necessary, in a controlled manner to supply electrical power or be charged by load/source 1320.

Referring to FIG. 10 a plurality of contoured wafers 1200 may be assembled together in a stack 1202 forming a plurality of flow channels 1206. The microfluidic flow channels 1206 created by combining the wafer 1200 into a stack allow close coupling of the electrodes. The reduced space in the electrodes allows strengthened electric fields (V/m) which in turn both reduces the needed ion drift distance to the membrane and improve the speed of transport through the membrane and across it, thus improving the performance of the electrochemical system or flow battery.

In existing zinc-based flow batteries, the uniformity of the electric field across the electrolyte is limited by technical challenges associated with solid metal electrode integration and design, control of their separation, and electrode shape. Further complicating operation and operational effectiveness is the fact that the plating uniformity is impacted by the chemical stoichiometry which will vary with interactions within the flowing fluid. Here the rate of plating and generation of secondary chemistry is non-uniform due to the varying chemical distribution resulting from the variations in laminar flow effects across the electrodes, relative to the input and output fluid ports. With the present disclosure, well controlled channels control the flow of the electrolyte relative to the electrodes. This use of non-linear flow channels in the battery allows for disruption of the laminar flow. This ensures constant mixing of electrolyte and uniform plating of the Anode, while the porous patterned Cathode allows for field shaping and increases surface area for efficient electron exchange.

“Conventional” zinc bromide batteries employ “Activated” Titanium Electrodes which employ a metallic coating to enhance initiation of the plating cycle and which limit the battery's operation and require electrode refurbishment. There are, however, a number of limitations associated with existing “conventional” zinc-based flow batteries that are avoided in the present disclosure. A schematic of a zinc-based battery operation in accordance with the present disclosure is shown in FIGS. 11(a) and 11(b) described below. This battery employs a patterned or large pore metal silicide anode surface to provide a large plating surface area.

Batteries made in accordance with the present disclosure preferably employ Titanium Silicide electrodes which will provide improved surface activation energy supporting enhanced chemical disassociation and plating efficiency. This change in materials allows the present disclosure to employ a single flow loop system and to eliminate the need for an ion exchange membrane. The use of a single loop reduces the volume of electrolyte required for the target energy storage level and the number of tanks and pumps required for managing the electrolyte. This is illustrated in FIGS. 11(a) and 11(b) which schematically illustrate the operation of the single electrolyte flow loop for a zinc-bromide (Zn/Br) or zinc-iodide (Zn/I) flow battery Cell; a) shows the Charging Cycle and b) the Discharging Cycle.

The present disclosure also provides for the integration of energy storage elements with photovoltaic cell elements whereby to permit direct charging of the battery, thereby eliminating the need for complex electrical distribution and conditioning circuits employed with conventional photovoltaic cells.

A conventional photovoltaic cell 10 is illustrated in FIG. 12. A conventional photovoltaic cell comprises a semiconductor silicon body 2012 of P-type conductivity which has been treated to provide a zone 2014 of N-type conductivity and a P-N junction 2016 near one surface 2018 which is to form the solar radiation gathering or receiving portion of the cell. It is customary to provide an electrode 2020 covering most of the shaded surface 2022 of the cell, i.e., the surface opposite surface 2018, and a second electrode in the form of a grid of narrow spaced conductors 2024 overlying the solar radiation gathering surface 2018. An anti-reflective coating 2026 is provided on the solar radiation gathering surface 2018 of the cell except where the grid-like electrode 2024 overlies the surface.

More particularly, the upper zone 2014 of the semiconductor silicon body 2012 is doped with, for example, phosphorous so that it has a slight excess of electrons, while the remainder lower zone of the semiconductor silicon body 2012 is doped with boron so that it has slightly too few electrodes. The upper zone 2014 is called the “N-type” or negative type silicon, while the lower zone is called the “P-type” zone or positive type silicon. The zone where the N-type and the P-type silicon contact one another, is called the “P-N junction” 2014. When the photovoltaic cell 2010 is illuminated by solar radiation, excess electrons from the P-type silicon zone are fused with holes in the P-type silicon zone wherein excess holes of the P-type silicon zone try to fuse with the excess electrons of the N-type silicon zone. This results in a flow of electrons which are removed from electrodes 2020 and 2024 by wires 2026 and 2028 to an external load 2030 which may include distribution and conditioning circuits.

FIG. 13 schematically shows a first embodiment of a photovoltaic cell having an integrated redox flow battery 2100 in accordance with the first embodiment of the present disclosure. The integrated photovoltaic cell/redox flow battery 2100 includes a photovoltaic cell 2101 which comprises a semiconductor monocrystalline silicon body 2102 of P-type conductivity which has been treated to provide a zone 2104 of N-type conductivity and a P-N junction 2106 near one surface 2108 forming the solar radiation gathering or receiving portion of the cell. A first electrode 2109 covers most of the shaded surface 2111 of the cell, i.e., the surface opposite surface 2108, and a second electrode in the form of a grid of spaced conductors 2110 is provided overlying surface 2108. An anti-reflective coating 2112 is provided on a light gathering surface 2108 of the cell except where the grid-like electrode 2110 overlies the surface.

The upper zone 2104 of semiconductor body 2102 is doped with, for example, phosphorous so that it has a slight excess of electrons, while the remainder lower zone of the semiconductor silicon body 2102 is doped with boron so that is has slightly too few electrodes.

As so described to this point photovoltaic cell 2100 of FIG. 14 is similar to the prior art photovoltaic cell 10 of FIG. 13. However, unlike prior art photovoltaic cells, the photovoltaic cell 2100 of the present disclosure is integrated with a redox flow cell battery 2120 whereby to permit direct energy charging of the battery. More particularly, redox flow cell 2120 incorporates electrode 2109 which is shared with photovoltaic cell 2100, and a further electrode 2122 which is spaced from electrode 2108 which is electrically connected to grid-like electrode 2110 via wire 2123. A semipermeable membrane 2124 is located between electrode 2109 and electrode 2122. Preferably semipermeable membrane 2124 comprises a porous silicon wafer made as described above. However, semipermeable membrane 2124 may comprise other suitable membrane materials formed, for example, of perfluorosulfonic acid polymers such a DuPont Nafion®. An electrolyte such as an iron-ligand electrolyte is flowed through a conduit 2126 between electrode 2109 and semipermeable membrane 2124, while an electrolyte is flowed through a conduit 2128 between electrode 2122 and semipermeable membrane 2124. Conduit 2126 and conduit 2128 are connected, respectively, via valves 2130 and 2132 and pumps 2134, 2136 to and from electrolyte reservoirs 2138 and 2140. When filled with electrolyte, electrode 2108, semipermeable membrane 2124 and conduit 2126 form a flow battery half-cell, while electrode 2122, semipermeable membrane 2124 and conduit 2128 form another flow battery half-cell. Reactant electrolytes are flowed through the half-cells, in a controlled manner and directly pick up and store electrical energy generated by photovoltaic cell 2101 from electrode 2110 and electrode 2122 as electrical energy is created by the photovoltaic cell 2101. Redox reactions occur at the surfaces of electrodes 2108 and 2122 according to the reactions as described in Table I above.

FIG. 14 is a view similar to FIG. 13 in which, however, the photovoltaic cell 2101A comprises a semiconductor silicon body 2102A of N-type conductivity which has been treated to provide a zone 2104A of a P-type conductivity. Aside from this distinction, the embodiment of FIG. 14 is essentially identical to the embodiment of FIG. 13, although the system is somewhat more efficient than the embodiment of FIG. 13.

FIG. 15 is a view similar to FIG. 13 in which, however, the photovoltaic cell 2100B is formed of polycrystalline silicon 2102B rather than monocrystalline silicon. Aside from employing polycrystalline silicon rather than monocrystalline silicon forming the photovoltaic cell, the photovoltaic cell/integrated redox flow cell battery of FIG. 14 is essentially the same as that of FIG. 13.

FIG. 16 is a view similar to FIG. 13, in which, however, the photovoltaic cell comprises a thin film solar cell 2101C. Thin-film solar cells are commercially available based on amorphous thin-film silicon semiconductor material, or other semiconductor materials including cadmium telluride and copper indium gallium diselenide, which are sandwiched between panes of glass. Aside from employing thin-film solar cells rather than monocrystalline silicon forming the photovoltaic cell, the photovoltaic cell/integrated redox flow cell battery of FIG. 16 is essentially the same as that of FIG. 13.

FIG. 17 is a view similar to FIG. 13 in which, however, the photovoltaic cell 2100D comprises a multi-junction solar cell. Multi-junction solar cells are available commercially and are made from multiple subcells 2150, 2152, 2154 having multiple bandwidths, assembled in a stack. For example, a multi-junction solar cell may comprise a top cell formed of, e.g., indium gallium phosphide, a middle cell formed of, e.g., indium gallium arsenide, and a bottom cell formed of, e.g., germanium. Multi-junction solar cells provide higher efficiency than those formed of, for example, monocrystalline silicon since multiple P-N junctions will produce electrical current and respond at different wave lengths of light. Thus, total efficiency of the cell is higher. However, aside from employing multi-junction solar cells rather than single junction monocrystalline silicon solar cells, the photovoltaic cell/integrated redox flow cell battery of FIG. 17 is essentially the same as that of FIG. 13.

Various changes may be made without departing from the spirit and scope of the disclosure. For example, various other III-V group compound semiconductor materials such as GaAs, InGaAs, InP, InAs, GaN, GaP, GaSb, InSb and InGaAsN may be used in forming the photovoltaic cells in connection with the above disclosure. Still other changes are possible.

As will be appreciated, by integrating photovoltaic cells and redox flow cell battery element, the disclosure permits direct solar charging of electrolytes, and thus storage of energy without the use of complex electrical distribution and conditioning circuits and without suffering their inherent loss. Also, the present disclosure permits handling of energy carrying electrolyte fluid in the fluid transport of energy from a point of generation at a photovoltaic cell directly to a point of use.

Referring to FIG. 18, an electrochemical etching cell useful for forming shaped porous silicon wafers in accordance with one embodiment of the present disclosure comprises an open tank 3202 comprising a bottom wall 3204, end walls 3206, 3208, and side walls (not shown). Tank 3202 is filled, at least in part, with a suitable silicon etchant 3210, such as DMF/DMSO/HF etchant. A platinum or the like electrode 3212 is immersed in the etchant 3210, and is connected via a circuit 3214 to a direct current source 3216. A silicon wafer holding fixture 3218 is immersed in the etchant 3210, spaced from the platinum electrode 3212. Silicon wafer holding fixture 3218 comprises a two piece assembly including an electrode carrier 3220 and a clamping element 3222, both formed of an electrically insulating material such as a plastic material. Electrode carrier 3220 has one or more spring electrodes 3224, and a connection circuit 3226 connected to a direct current source 3216. Alternatively, spring electrodes 3224 may comprise electrode sponges which are available commercially from a variety of vendors. Electrode carrier 3220 includes a stepped frame area 3230 having a groove 3232 in which an O-ring 234 is located. Clamping element 3222 also includes a groove 3236 for accommodating an O-ring 3238. In use, a silicon wafer 3240, having a contact metal layer 3242 formed of, e.g., Titanium, Titanium Silicide or Aluminum is deposited on one side of the wafer, is held between the electrode carrier 3220 and the clamping element 3222, sandwiched between O-rings 3234 and 3238. The electrode carrier 3220 and the clamping element 3222 are held together with release elements such as nylon or plastic bolts 3244 and nuts 3246, or nylon or plastic screws 3248.

Rather than employing spring loading plate electrodes, a wire “tongue” or the like may be provided against the wafer. Also, for in bath electrodes, noble metals such as platinum or gold are the best choice as they are inert. However, other materials such as stainless steel, brass, tungsten or aluminum can be used if the electrochemical cell is designed to prevent the electrical contact from exposure to the etching electrolyte (i.e. etchant). Still other changes are possible.

Referring to FIG. 19, a silicon wafer 3240 is coated on one side with a metal layer 3242 such as Titanium, Titanium Silicide or Aluminum by sputtering in a coating step 3260. Metal layer 3242 may be quite thin, e.g., 0.1 to 5 microns. Metal layer 3242 acts as a back electrode in a subsequent electrochemical etching step as will be described below. The metal coated silicon wafer is then clamped in silicon wafer holding fixture 3220, with the metal layer 3242 facing the spring electrodes 3224, immersed in the etchant 3210, and current is applied between spring electrodes 3224 and electrode 3212 in an electrochemical etching step 3262. The metal coating 3242 or back electrode provides a large uniform coupling of the field/current across the exposed surface of the silicon wafer 3240 resulting in a substantially uniform etching of through holes through the silicon wafer. After etching, the etched silicon wafer is removed from the etchant 3210, washed in a washing step 3264, and the metal layer 3242 is stripped from the back side of the wafer in a stripping step 3266, using a suitable stripper such as Kroll's reagent, which is a mixture of nitric acid, hydrofluoric acid and water, or another commercially available targeted metal etchant. The wafer is then washed again in a washing step 3268, and is ready to use.

There results a porous silicon wafer having substantially uniform size pores extending therethrough, substantially uniformly covering the surface of the wafer.

Referring to FIG. 20, an electrochemical etching cell in accordance with another embodiment of the present disclosure comprises a closed cell etching chamber 3300. Etching chamber 3300 includes a silicon wafer holding fixture 3302, an electrode which comprises a two piece assembly including a base member 3304 for supporting a silicon wafer 3306 backed by a contact metal layer 3308, and a clamping member 3310. Base member 3304 and clamping member 3310 are formed of an electrically insulating material such as a plastic material. Base member 3304 includes a groove 3312 in which an O-ring 3314 is located. In use the metal backed silicon wafer 3304 is sandwiched between base member 3304 and clamping member 3310 which are held together by release elements such as nylon or plastic bolts 3316 and nuts 3318. As so described to this point, fixture 3302 is similar to 3218 shown in FIG. 18. However, in the FIG. 20 embodiment fixture 3302 is closed by an alumina or a sapphire sheet 3320 which is clamped to the top of holding element 3310 by a clamping element 3322 which is fixed to holding element 3310 by bolts 3324, whereby to form a self-contained etch chamber. To ensure a liquid tight chamber, clamping element 3310 includes a groove 3326 in which is located an O-ring 3328. Metal layer 3308 is connected via a spring electrode and a circuit 3330 to a one side of a direct current source 3332, and a platinum electrode 3334 is imbedded through the wall of clamping element 3310 and connected via a circuit 3336 the other side of current source 3332. Optionally, platinum electrodes may be deposited directly on the chamber side of the sapphire cover 3320 or the chamber side of holding element 3310.

The present disclosure provides several important advantages. For one, the wafer holders allows the wafer to be held in a manner which controls its exposure to the electrolyte. This allows the wafer contact electrode to make dry contact to the wafer such that aluminum or other metal electrodes not compatible with the electrolyte can be used, greatly reducing associated costs and complexity. The immersed fixture (FIG. 18) allows the wafer to be easily transported between baths. The closed fixture (FIG. 20) permits direct electrical connection to the electrolyte in close proximity to the wafer. Also, in the case of the closed cell (FIG. 20), the volume of fluids, in particular, the electrolyte required is significantly reduced as compared to the open cell approach. Reduction of fluid demands provides significant cost savings as well as reduced environmental issues with waste deposable.

Chamber 3300 also includes inlets and outlets (not shown) for connection to sources of etching electrolytes, wash fluid, etc. through conduits and valves and pumps as described below in FIG. 21.

Referring to FIG. 21, the overall system and process is as follows: the process includes steps of: (i) removal of organic contaminants, (ii) removal of the native oxide layer and (iii) removal of ionic contaminations; and (iii) etching. To begin with, a silicon wafer having a metal layer applied to one side, as described before, is loaded into chamber 3300 with the uncovered surface of the silicon wafer facing the interior of the chamber, and the chamber is sealed closed.
Thereafter organic residues and contaminant particles are removed from the exposed surface of the silicon wafer, using a suitable cleaning solution such as mixture of de-ionised water, ammonium hydroxide (NH₄OH) and hydrogen peroxide (H₂O₂) from a source 3402 delivered to the chamber 3300 via pump 3404, conduits 3406 and valve 3408. This step cleans the surface of the silicon wafer, and results in the formation of a layer of silicon dioxide with controlled thickness (i.e. 10-30 angstroms).
Then, the silicon wafer is subjected to a short exposure of a mixture of HF and water from a source 3410 via pump 3412, conduit 3414 and valve 3416, which removes the native oxide layer and some fraction of ionic contaminants that might be present on the surface of the silicon wafer.
Then any remaining traces of metallic contaminants are removed, and a thin passivating layer is formed on the exposed surface of the wafer, by exposing the silicon wafer to a suitable cleaning solution such as a mixture of water, hydrochloric acid (HCl) and H₂O₂ from a source 3420 delivered via a pump 3422, conduit 3424 and valve 3426.

Following these pre-treatments, silicon wafers are electrochemically etched as described above, the metal layer is stripped from the back side of the wafer, and the wafer is washed and ready to use to produce porous Si structures.

Referring to FIG. 22 and FIG. 23A there is illustrated a redox flow electrical storage battery system 4040 made in accordance with the present disclosure. The redox flow electrical energy storage battery 4040 includes a pair of half-cells 4042, 4044 separated by a porous membrane 4046. An anolyte electrolyte 4048 is flowed through half cell 4042, and a catholyte electrolyte 4050 is flowed through half cell 4044. An anode electrode 4052 is located in half cell 4042 and a cathode electrode 4054 is located in half cell 4044. Electrodes 4052 and 4054 are in turn in contact with anolyte electrolytes 4048 and catholyte electrolyte 4050 respectively. Anode electrode 4052 and cathode electrode 4054 are connected to a source or load 4056. Analyte electrolyte 4048 and catholyte electrolyte 4050 are introduced into and flowed through half cells 4042 and 4044, respectively via conduits 4058 and 4060, respectively, and withdrawn from half cells 4042 and 4044 via conduits 4062 and 4064, respectively, such that redox reactions occur at the surfaces of electrodes 4052 and 4054. For ease of illustration, electrolyte circulating pumps and valves are omitted.

In order to increase mixing of the electrolyte as it is flowed through the half cells 4042 and 4044, a plurality of dividers or barriers 4066A, 4066B are formed in half cells 4042 and 4044 creating flow channels 4066A configured essentially parallel to one another running essentially the length of the half cells 4042 and 4044. Dividers or barriers 4066A introduce turbulence insuring that the electrolyte fluids are always changing or mixing at the surfaces of the electrodes 4052 and 4054 and the membrane 4046. FIG. 23B is similar to FIG. 23A in which however the dividers or barriers 4066A, 4066B are reduced in spacing to create more narrow channels 4068A, 4068B. Referring to FIG. 23C, alternatively, the barriers may be configured as interdigitized “fingers” 4070A, 4070B, essentially forming an elongate serpentine channel 4072 between the inlet and outlet. Providing a serpentine channel 4072 effectively increases channel length, introduces variations in flow velocity, and adds turbulence to further mix the electrolyte solution insuring the solution is always changing at the surface of the electrodes and the membrane. FIG. 23D is similar to FIG. 23C but in which the fingers 4070C, 4070D are at narrower spacings thus increasing the length of the channel 4072.

Referring to FIGS. 24 and 25, there are illustrated other examples of redox flow energy storage battery half-cells having flow channels or barriers configured to optimize interaction of the electrolyte with the electrodes and membranes in accordance with the present disclosure. FIG. 24 illustrates a plurality of half cells 4080, 4082, 4084 arranged in parallel to one another and having a common inlet manifold 4088 and a common outlet manifold 4090. FIG. 25 shows a plurality of half cells 4092, 4094, 4096 configured together in series with the outlet manifold 4098 of a first downstream half cell 4092 being connected to the inlet manifold 4100 of the second half cell 4094 in series, and so forth.

Referring to FIG. 26, starting with a monocrystalline silicon wafer 5110, typically 100 to 700 microns thick, the wafer 5110 is subjected to an electrochemical etching by applying uniform electrical field across the wafer while immersing the wafer in an etchant such a Dimethylformamide (DMF)/Dimethylsulfoxide (DMSO)/HF etchant in an electrochemical immersion cell, in an electrochemical etching step 5112, to form micron sized through holes or pores 5116 through the wafer as shown in FIG. 27A. The growth of well-defined cylindrical micropores or through holes can be controlled by controlling etching conditions, i.e., etching current density, etchant concentration, temperature, silicon doping, etc., following the teachings of Santos et al., Electrochemically Engineered Nanoporous Material, Springer Series in Materials Science 220 (2015), Chapter 1, the contents of which are incorporated herein by reference.

The resulting pores have a high aspect ratio of length to cross-sectional diameter typically a depth to cross section dimension aspect ratio of ≤50:1. The resulting structure, shown in FIG. 27A comprises a porous silicon wafer 5118 having substantially cylindrical through holes or pores 5116 having a length of, e.g., 180 μm and a diameter of 1.6 μm, i.e, an aspect ratio of 112.5:1 which is quite effective for use as electrode in a lithium ion battery as will be described below. The walls of the resulting porous silicon wafer 5118 are then coated with a metal such as titanium or tungsten, or amorphous carbon, in step 5120, and the metal coated porous silicon wafer is then subjected to a heat treatment in a heating step 5122 to convert the deposited metal to the corresponding metal silicide 5125 at heat treatment step 5122. There results a porous silicon substrate material 5124 in which the wall surfaces of the pores of the material are coated with a metal silicide material 5126 (FIG. 27B). Preferably the metal silicon material layer 5126 has a thickness of 0.1 to 100 μm.

FIG. 28 illustrates an alternative embodiment of the present disclosure. The process starts with a silicon wafer 5130 to which is applied a thin metal layer 5132 on the back side of the wafer 5130 e.g., by sputtering in a step 5134. Metal layer 5132 on the backside of the wafer promotes improved electrical contact to the wafer. An electro chemical etching step 5136 is used to form pores through the silicon wafer 5130. After porous silicon formation, a wet etch step 5138 is used to remove the thin metal 132 from the back side. The porous silicon wafer which is similar to the porous silicon substrate shown in FIG. 27A is then coated with metal in step 5140 and the metal converted to the silicide in a heating step 5142 similar to the first embodiment. There results a porous silicon substrate in which the surface of the wall surfaces of the pores are coated with a metal silicide similar to the porous silicon substrate shown in FIG. 27B.

FIG. 29 illustrates a third embodiment of the present disclosure. The process starts with a silicon wafer 5150 covered on one side in step 5152 with a sacrificial metal layer 5154 formed of, for example, a noble metal such as platinum. The silicon wafer 5150 is then subjected to electrochemical etching by applying an uniform electrical field across the metal layer 5154 and substrate wafer 5150 as the wafer is immersed in an electrochemical cell containing an etchant such as HF and H₂O₂, in step 5156, whereby to produce substantially uniform pores 5158 through the exposed portion of the silicon wafer substrate 5150 to the metal layer 5154. As before, the growth of well-defined cylindrical micropores or through holes can be controlled by controlling etching conditions, i.e., etching current density, etching concentration, temperature, silicon doping, etc., again following the teachings of Santos et al. Alternatively, micropore or through hole formation can be controlled by covering selected portions of the silicon wafer with a nanoporous anodic alumina mask. Self-ordered nano porous anodic alumina is basically a nanoporous matrix based on alumina that features closed-packed arrays of hexagonally arranged cells, at the center of which a cylindrical nanopore grows perpendicularly to the underlying aluminum substrate. Nanoporous anodic alumina may be produced by electrochemical anodization of aluminum, again following the teachings of Santos et al. the teachings of which are incorporated herein by reference. The sacrificial metal layer 5154 can then be removed in a step 5158 leaving a porous silicon wafer having substantially cylindrical through holes or pores having a length to diameter aspect ratio of >50:1, i.e., similar to the porous silicon substrate shown in FIG. 27A. The porous silicon substrate is then coated with metal in step 5158, and heated to convert the metal to the metal silicide in step 5160, whereby a porous silicon substrate in which the wall surfaces of the pores are coated with metal silicide similar to FIG. 27B is produced.

Porous silicon wafers as produced above are assembled into a lithium ion battery as will be described below.

FIG. 31 shows a membrane-less redox flow electrical energy storage battery 5160 in accordance with the present disclosure. Battery 5160 includes a case 5162 an anode electrode 5164 formed of a metal silicide coated porous silicon substrate formed as above described, and a cathode electrode 5166 formed, for example, of graphite. Anode 5164 and cathode 5166 are connected to a load 5170. A zinc/halide containing electrolyte 5174, for example, zinc/bromide is flowed form a reservoir 5176 through the battery 5160. Electrolyte 5174 also may comprise zinc/iodide.

Referring to FIGS. 32 and 33 during charging the zinc bromide is dissociated and the positive zinc ions move into the anode electrode, and the negative bromide ions move into the positive zinc ions. During discharge, the positive zinc ions move from the anode electrode and the bromide ions move from the cathode electrode reforming zinc bromide while the electrons flow through the external circuit in the same direction. When the cell is recharged, the reverse occurs and the zinc bromide is dissociated, with the zinc ions and the electrons moving back into the anode electrode and he bromide ions moving back into the cathode net higher energy stake.

A feature an advantage of the present disclosure is that the anode may be made physically larger, i.e., thicker than the cathode. The increased thickness porous structure of the anode allows protons more time to move into the electrode matrix. Also, less electrolyte is required for similar energy storage. And, since the protons move more slowly into the anode, this permits a faster charge and discharge rate without a danger of fractures or pulverization of the electrode.

Changes may be made in the above disclosure without departing from the spirit and scope thereof. For example, while the porous electrode production has been described as being formed from monocrystalline silicon wafers, monocrystalline silicon ribbon advantageously may be employed for forming the anode. Referring to FIG. 30, employing silicon ribbon 5180 permits a continuous process in which ribbon is run through an electrochemical etching bath 5182 to form pores through the ribbon, and then from there through a metal coating station 5184 and from there a heat treating station 5186 to form metal silicide on the surfaces of the walls of the pores. The resultant porous silicon metal silicide coated ribbon may then be cut to size in a cutting station 5188 and assembled in a membrane-less redox flow electrical energy storage battery such as described above.

Referring to FIG. 34 an alternative form of membrane-less redox flow electrical energy storage battery 5200 is shown. Battery 5200 is similar to battery 5160 shown in FIG. 31, and includes a case 5202, anode electrode 5204 and cathode electrode 5206. However, in the FIG. 34 embodiment, cathode 5206 comprises a solid metal or carbon substrate 5208 covered with a metal silicide coated porous silicon electrode material 5210 as described above, facing the electrolyte 5212. Alternatively, the anode may comprise a solid metal or carbon substrate covered with a metal silicide coated porous silicon electrode material as described above. As before, electrolyte 5214 such as, for example, zinc/bromide is flowed from a reservoir 5216 through the battery 5200. Battery 5200 operates similarly to battery 5160 described above with positive zinc ions moving into and out of the anode electrode 5204, and bromide ions moving into and out of the cathode electrode 5206.

Still other changes are possible. For example, rather than using monocrystalline silicon chips or monocrystalline silicon ribbon, the silicon may be polysilicon silicon or amorphous silicon. Also, while tungsten and titanium have been described as the preferred metals for forming the metal silicide coated electrodes, other conventionally used in forming advantageously may be employed including silver (Ag), aluminum (Al), gold (Au), palladium (Pd), platinum (Pt), Zn, Cd, Hg, B, Ga, In, Th, C, Si, Ge, Sn, Pb, As, Sb, Bi, Se and Te. Also, while the use of iron-ligand and iron-chloride electrolytes has been disclosed, other redox electrolytes such as, but not limited to vanadium based electrolytes, such as vanadium-chloride based electrolytes, zinc based electrolytes such as zinc-bromide and zinc iodide based electrolytes, sulfuric acid-based electrolytes, and iron-chromium electrolytes may be used. Still other changes are possible

What is claimed:

1. A battery comprising a separator membrane element formed of a porous silicon wafer.

2. The battery of claim 1, wherein pores of the porous silicon wafer are substantially cylindrical through holes, and wherein the cylindrical through holes preferably have a depth to cross section dimension aspect ratio of ≤50:1.

3. The battery of claim 1, wherein surfaces of pores of the porous silicon wafer are treated to enhance surface ion conductivity; wherein the surfaces of the pores are oxidized, or the surfaces are modified by deposition of a metal; and/or wherein the porous silicon wafer is doped to enhance metal ion rejection and proton conductivity.

4. The battery of claim 1, wherein the battery comprises a redox flow battery comprising:
an electrical assembly comprising positive and negative electrodes respectfully located in half-cells separated by a separator membrane, wherein the separatomembrane comprises a porous silicon wafer.

5. The redox flow battery of claim 4, further comprising an electrolyte in the half-cells, and further wherein the electrolyte preferably is selected from the group consisting of iron-ligand electrolyte, an iron-chloride electrolyte, and iron-chromium electrolyte, a vanadium-based electrolyte, a sulfuric acid-based electrolyte a hydrochloric acid electrolyte, a zinc-bromide electrolyte, a zinc-iodide electrolyte, a zinc-cerium electrolyte, a zinc-nickel electrolyte, and a zinc-iron electrolyte such as zinc-ferricyanide.

6. A method of forming a separator for use in a battery, comprising: providing a silicon wafer; and etching through holes extending through at least a portion of the wafers, wherein the through holes preferably have a depth to cross section dimension aspect ratio of ≤50:1.

7. The method of claim 6, further comprising the step of treating surfaces of the pores to enhance surface ion conductivity; wherein the surfaces of the pores are oxidized, or the surfaces are modified by deposition of a metal; and/or wherein the silicon wafer is doped to enhance metal ion rejection and proton conductivity.

8. The method of claim 6, wherein the battery comprises a redox flow battery.

9. redox flow battery system comprising a plurality of paired half-cells in which the paired half-cells each have a separator membrane element formed at least in part of a porous silicon wafer.

10. The battery system of claim 9, wherein pores of the porous silicon wafer are substantially cylindrical through holes preferably having a depth to cross section dimension aspect ratio of ≤50:1, wherein surfaces of pores of the porous silicon wafer are treated to enhance surface ion conductivity; and/or wherein the surfaces of the pores are oxidized, or the surfaces are modified by deposition of a metal and wherein the porous silicon wafer is doped to enhance metal ion rejection and proton conductivity.

11. The battery system of claim 9, further comprising: positive and negative current collectors respectively located in the half-cells, and wherein the paired half-cells are arranged in a stack, and in which adjacent half-cells in the stack share a common current collector.

12. The battery system of claim 9, wherein the separator member comprises a shaped porous silicon wafer having a porous middle section of a first thickness, and solid silicon end sections of a second thickness greater than the middle section.

13. The battery system of claim 12, further comprising an electrolyte in the half-cells, wherein the electrolyte preferably is selected from the group consisting of an iron-ligand electrolyte, an iron-chloride electrolyte, and iron-chromium electrolyte, a vanadium-based electrolyte, a sulfuric acid-based electrolyte, a hydrochloric acid electrolyte, a zinc-bromide electrolyte, a zinc-iodide electrolyte, a zinc-cerium electrolyte, a zinc-nickel electrolyte, and a zinc-iron electrolyte such as zinc-ferricyanide; and wherein the battery includes metal silicide electrodes selected from the group consisting of titanium silicide, tungsten silicide, platinum silicide, and palladium silicide.

14. A solar energy generation and storage system comprising a photovoltaic cell and an electrochemical energy storage battery, wherein the photovoltaic cell and the electrochemical storage battery share a common electrode.

15. The solar energy generation and storage system of claim 14, wherein the electrochemical energy storage battery comprises a redox flow battery, and wherein the redox flow battery incorporates at least one of a porous silicon membrane and a membrane formed of a perfluorosulfonic acid polymer.

16. The solar energy generation and storage system of claim 14, wherein the photovoltaic cell comprises a silicon solar cell or a gallium arsenide cell, and wherein the silicon solar cell comprises a monocrystalline silicon solar energy cell having a monocrystalline silicon body of P-type conductivity which has been treated to provide a zone of N-type conductivity, or a monocrystalline silicon body of N-type conductivity which has been treated to provide a zone of P-type conductivity, or wherein the photovoltaic cell comprises a polycrystalline silicon cell, or a thin-film solar cell which comprises a semi-conductor material selected from the group consisting of amorphous thin-film silicon, cadmium telluride and copper indium gallium diselenide.

17. The solar energy generation and storage system of claim 14, wherein the photovoltaic cell comprises a multi junction solar cell which comprises gallium phosphide, a middle cell formed of indium gallium arsenide, and a bottom cell formed of germanium.

18. An electrochemical etching system for forming porous silicon wafers in a electrochemical etch chamber, the chamber including platinum electrode connected to a current source, an etching electrolyte, and a fixture for holding a silicon wafer having a metal layer on its back surface for contact with the etching electrolyte, the fixture comprising a two piece assembly including an electrode carrier and a clamping element, both formed of an electrically insulating material, wherein the electrode carrier has one or more electrodes configured to connect the back surface of the silicon wafer to a circuit connected to the current source.

19. The system of claim 18, wherein the silicon wafer is sandwiched between O-rings between the electrode carrier and the clamping element, or wherein the electrode element and clamping element are held together with bolts and nuts or screws.

20. The system of claim 18, wherein the resilient electrodes comprise spring electrodes or electrode sponges, and/or wherein the fixture includes a removable cover which cover, which cover when installed on the fixture forms a fluid tight etch chamber.

21.-39. (canceled)
